(19) United States
(12) Patent Application Publication
(10) Pub. No.: US 2020/0028118 A1
(43) Pub. Date: Jan. 23, 2020

(54) LIGHT-EMITTING SYSTEM

(71) Applicant: PIONEER CORPORATION, Bunkyo-ku, Tokyo (JP)

(72) Inventor: Chihiro HARADA, Bunkyo-ku, Tokyo (JP)

(21) Appl. No.: 16/337,905

(22) PCT Filed: Sep. 28, 2016
(86) PCT No.: PCT/JP2016/078675

§ 371 Date: Mar. 28, 2019

(51) Int. Cl. H01L 51/52; H01L 51/10; H01L 51/00

(52) U.S. Cl. CPC H01L 51/5275; H01L 51/0096; H01L 51/102

(57) ABSTRACT

The refractive index of a third region (430) (base material (200)) is closer to the refractive index of a first region (410) (adhesive layer (310)) than to the refractive index of a second region (420) (gap (320)). Put differently, the absolute value of a refractive index difference between a first medium (510) (adhesive layer (310)) and a third medium (530) (base material (200)) is smaller than the absolute value of a refractive index difference between a second medium (520) (gap (320)) and the third medium (530) (base material (200)). Thus, it is possible to inhibit light advancing from the first region (410) (adhesive layer (310)) side to the third region (430) (base material (200)) side from being reflected on a boundary (552) and to inhibit light advancing from the third region (430) (base material (200)) side to the second region (420) (gap (320)) side from passing through a boundary (554).

### TECHNICAL FIELD

The present invention relates to a light-emitting device.

### BACKGROUND ART

In recent years, there has been progress in the development of organic light-emitting diodes (OLEDs) having optical transparency. For example, an OLED described in Patent Document 1 includes a substrate having light-transmitting properties, an electrode having light reflectivity, and a light scattering layer. The electrode and the light scattering layer face each other with the substrate interposed therebetween. In addition, an OLED in Patent Document 2 includes a first transparent electrode layer, an organic layer, a second transparent electrode layer, and a mirror layer. The organic layer is located between the first transparent electrode layer and the second transparent electrode layer and includes an electroluminescent region and a non-electroluminescent region. The mirror layer is located over the second transparent electrode layer and overlaps the electroluminescent region.

One example of a liquid crystal display is described in Patent Document 3. This liquid crystal display includes a transparent plate, a liquid crystal panel, a light-emitting element, and a transparent sheet. The liquid crystal panel is located on the front surface of the transparent plate, and the liquid crystal panel is on the rear surface of the transparent plate. The transparent sheet faces the rear surface of the transparent plate with an air layer interposed therebetween.

### RELATED ART DOCUMENTS

### Patent Documents

[Patent Document 1]: Japanese Unexamined Patent Application Publication No. 2013-149376
[Patent Document 2]: Japanese Unexamined Patent Application Publication (Translation of PCT Application) No. 2012-506604
[Patent Document 3]: Japanese Unexamined Patent Application Publication No. 10-149881

### SUMMARY OF THE INVENTION

A light-emitting device having light-transmitting properties (for example, OLED) maybe installed on a base material (for example, a rear window of an automobile). In such a case, when light from the light-emitting device is emitted from one surface of the base material, the light is desired to be inhibited from leaking from the opposite surface of the base material.

An example of the problem to be solved by the present invention is to inhibit light from a light-emitting device having light-transmitting properties installed on a base material from leaking from a side opposite to a light-emitting side.

### Means for Solving the Problem

The invention described in claim 1 is a light-emitting system including:

a base material having a light-emitting first surface; and

a light-transmitting substrate including a second surface facing a side opposite to the base material, and a plurality of light-emitting regions and a plurality of light-transmitting regions which are alternately aligned, the light-transmitting substrate supported by the base material,

in which a region between the first surface and the second surface includes:
a first region overlapping any of the plurality of light-emitting regions;
a second region overlapping any of the plurality of light-transmitting regions; and
a third region overlapping the first region and the second region, and

in which a refractive index of the third region is closer to a refractive index of the first region than to a refractive index of the second region.

The invention described in claim 12 is a light-emitting system including:

a base material having a light-emitting first surface; and

a light-transmitting substrate including a second surface facing a side opposite to the base material, and a plurality of light-emitting regions and a plurality of light-transmitting regions which are alternately aligned, the light-transmitting substrate supported by the base material,

in which a region between the first surface and the second surface includes:
a first boundary located between a first medium and a third medium, the first boundary overlapping any of the plurality of light-emitting regions; and

a second boundary located between a second medium and the third medium, the second boundary overlapping any of the plurality of light-transmitting regions, and

in which an absolute value of a refractive index difference between the first medium and the third medium is smaller than an absolute value of a refractive index difference between the second medium and the third medium.

The invention described in claim 17 is a light-emitting system including:

a base material having a light-emitting first surface; and

a light-transmitting substrate including a second surface facing a side opposite to the base material, and a plurality of light-emitting regions and a plurality of light-transmitting regions which are alternately aligned, the light-transmitting substrate supported by the base material,

in which a region between the first surface and the second surface includes:
a first region overlapping any of the plurality of light-emitting regions; and
a second region overlapping any of the plurality of light-transmitting regions, and

in which a refractive index of the second region is smaller than a refractive index of the first region.

### BRIEF DESCRIPTION OF THE DRAWINGS

The objects described above, and other objects, features and advantages are further made apparent by suitable embodiments that will be described below and the following accompanying drawings.

FIG. 1 is a diagram of a light-emitting system according to a first embodiment.

FIG. 2 is an enlarged diagram of a region a of FIG. 1.

FIG. 3 is a diagram in which a light-emitting device is removed from FIG. 2.

FIG. 4 is a cross-sectional view taken along line A-A of FIG. 2.

FIG. 5 is a cross-sectional view taken along line B-B of FIG. 2.

FIG. 6 is a diagram to explain a first example of a method to join a light-emitting device shown in FIGS. 1 to 5 to a base material.

FIG. 7 is a diagram to explain a second example of a method to join a light-emitting device shown in FIGS. 1 to 5 to a base material.

FIG. 8 is a diagram to explain the operation of the light-emitting system shown in FIGS. 1 to 5.

FIG. 9(a) is a diagram to explain a first example of an adhesive layer shown in FIGS. 1 to 5, FIG. 9(b) is a diagram to explain a second example of the adhesive layer shown in FIGS. 1 to 5, FIG. 9(c) is a diagram to explain a third example of the adhesive layer shown in FIGS. 1 to 5, and FIG. 9(d) is a diagram to explain a fourth example of the adhesive layer shown in FIGS. 1 to 5.

FIG. 10(a) is a diagram to explain a first example of details of a light-emitting unit shown in FIG. 4, and FIG. 10(b) is a diagram to explain a second example of details of the light-emitting unit shown in FIG. 4.

FIG. 11 is a diagram showing a first modification example of FIG. 3.

FIG. 12 is a diagram showing a second modification example of FIG. 3.

FIG. 13 is a diagram showing a first modification example of FIG. 4.

FIG. 14 is a diagram showing a second modification example of FIG. 4.

FIG. 15 is a diagram showing a third modification example of FIG. 4.

FIG. 16 is a diagram showing a fourth modification example of FIG. 4.

FIG. 17 is a diagram showing a fifth modification example of FIG. 4.

FIG. 18 is a cross-sectional view showing a light-emitting system according to a second embodiment.

FIG. 19 is a diagram showing a first modification example of FIG. 18.

FIG. 20 is a diagram showing a second modification example of FIG. 18.

FIG. 21 is a diagram showing a third modification example of FIG. 18.

FIG. 22 is a diagram showing a fourth modification example of FIG. 18.

FIG. 23 is a diagram showing a fifth modification example of FIG. 18.

FIG. 24 is a cross sectional view of a light-emitting system according to a third embodiment.

FIG. 25 is a diagram showing a modification example of FIG. 24.

FIG. 26 is a cross sectional view of a light-emitting system according to a fourth embodiment.

FIG. 27 is a diagram showing a modification example of FIG. 26.

FIG. 28 is a diagram of a light-emitting system according to an example.

### DESCRIPTION OF EMBODIMENTS

Embodiments of the present invention will be described below by referring to the drawings. Moreover, in all the drawings, the same constituent elements are given the same reference numerals, and descriptions thereof will not be repeated.

### First Embodiment

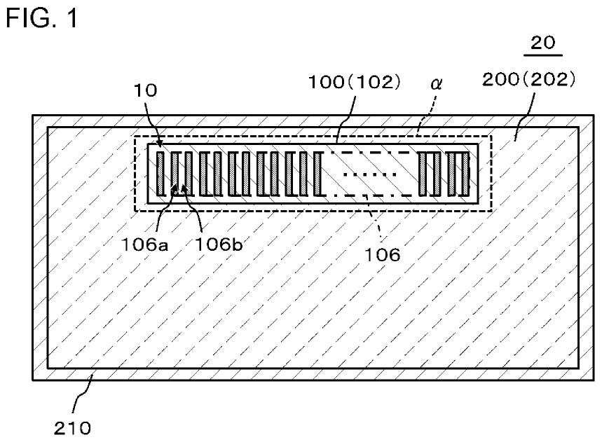

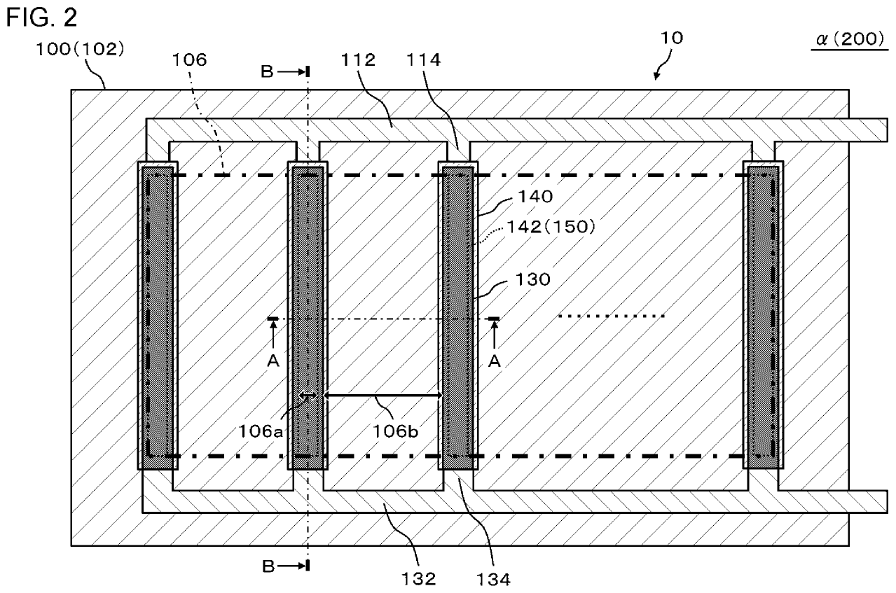

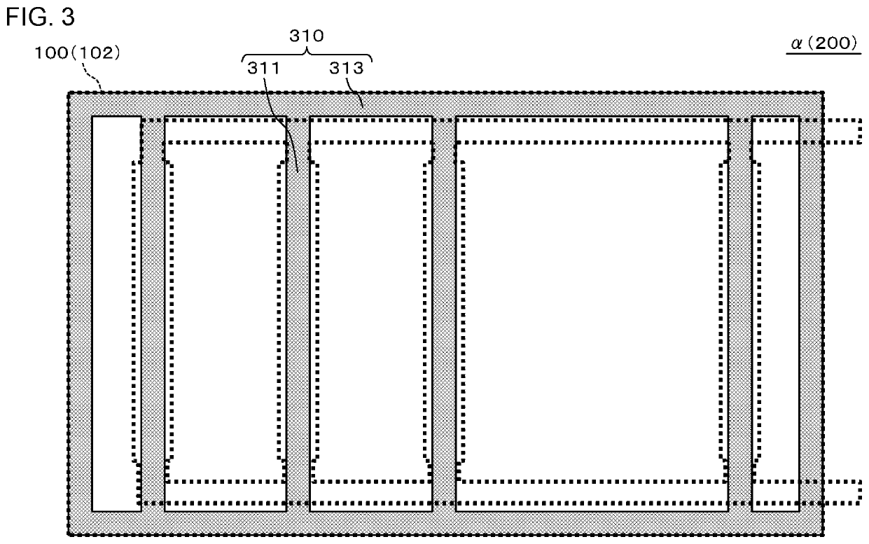

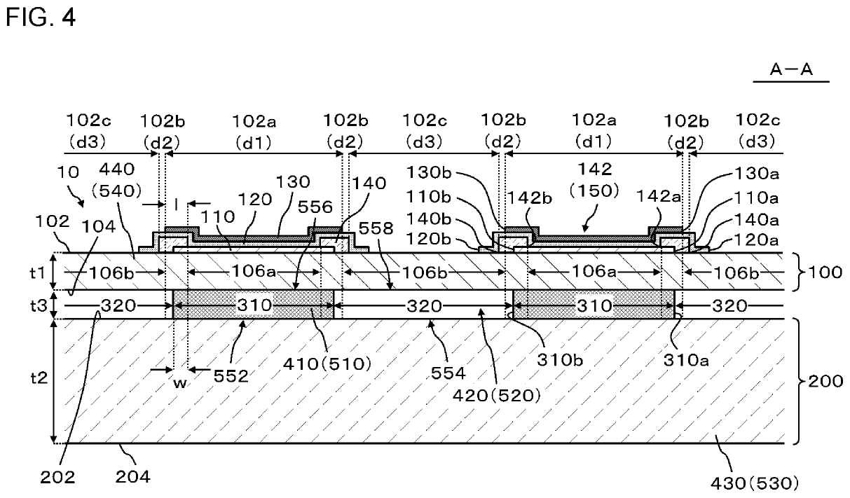

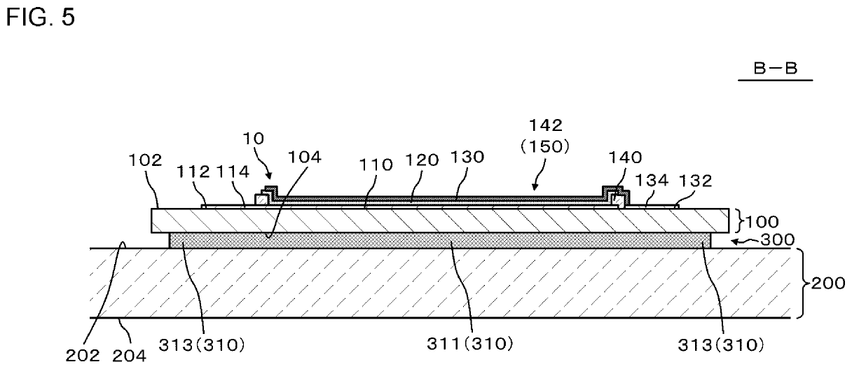

FIG. 1 is a diagram of a light-emitting system 20 according to the first embodiment. FIG. 2 is an enlarged diagram of a region a of FIG. 1. FIG. 3 is a diagram in which a light-emitting device 10 is removed from FIG. 2. FIG. 4 is a cross-sectional view taken along line A-A of FIG. 2. FIG. 5 is a cross-sectional view taken along line B-B of FIG. 2.

A summary of the light-emitting system 20 is explained using FIG. 4. The light-emitting system 20 includes a substrate 100 and a base material 200. The base material 200 has a surface 204 (first surface). The substrate 100 has light-transmitting properties. The substrate 100 has a surface 102 (second surface). The surface 102 of the substrate 100 faces to a side opposite to the surface 204 of the base material 200. The substrate 100 includes a plurality of light-emitting regions 106a and a plurality of light-transmitting regions 106b. These light-emitting regions 106a and the light-transmitting regions 106b are alternately aligned. The substrate 100 is supported by the base material 200. In other words, the base material 200 functions as a support to support the substrate 100.

A region between the surface 204 of the base material 200 and the surface 102 of the substrate 100 includes a plurality of first regions 410, a plurality of second regions 420, a third region 430, and a fourth region 440. Each of the plurality of first regions 410 overlaps respective ones of the plurality of light-emitting regions 106a. Each of the plurality of second regions 420 overlaps respective ones of the plurality of light-transmitting regions 106b. The third region 430 overlaps the plurality of first regions 410 and the plurality of second regions 420. The fourth region 440 faces the third region 430 with the plurality of first regions 410 and the plurality of second regions 420 interposed therebetween.

In the example shown in the diagram, each of a plurality of adhesive layers 310 functions as each of the plurality of first regions 410, each of a plurality of gaps 320 functions as each of the plurality of second regions 420, the base material 200 functions as the third region 430, and the substrate 100 functions as the fourth region 440.

The region between the surface 204 of the base material 200 and the surface 102 of the substrate 100 includes a plurality of boundaries 552, a plurality of boundaries 554, a plurality of boundaries 556, and a plurality of boundaries 558. Each of the plurality of boundaries 552 is located between a first medium 510 and a third medium 530 and overlaps respective ones of the plurality of light-emitting regions 106a. Each of the plurality of boundaries 554 is located between a second medium 520 and the third medium 530 and overlaps respective ones of the plurality of light-transmitting regions 106b. Each of the plurality of boundaries 556 is between the first medium 510 and a fourth medium 540, each of the plurality of boundaries 556 overlapping respective ones of the plurality of light-emitting regions 106a, and is located on the opposite side of each of the plurality of boundaries 552 with the first medium 510 interposed therebetween. Each of the plurality of boundaries 558 is between the second medium 520 and the fourth medium 540, each of the plurality of boundaries 558 overlapping respective ones of the plurality of light-transmitting regions 106b, and is located on the opposite side of each of the plurality of boundaries 554 with the second medium 520 interposed therebetween.

In the example shown in the diagram, each of the plurality of adhesive layers 310 functions as each of a plurality of first media 510, each of the plurality of gaps 320 functions as each of a plurality of second media 520, the base material 200 functions as the third medium 530, and the substrate 100 functions as the fourth medium 540.

The refractive index of the third region 430 (base material 200) is closer to the refractive index of the first region 410 (adhesive layer 310) than to the refractive index of the second region 420 (gap 320). In other words, the absolute value of a refractive index difference between the first medium 510 (adhesive layer 310) and the third medium 530 (base material 200) is smaller than the absolute value of a refractive index difference between the second medium 520 (gap 320) and the third medium 530 (base material 200). In this case, the light reflectance on an interface (boundary 552) between the first region 410 (adhesive layer 310) and the third region 430 (base material 200) is smaller than the light reflectance on an interface (boundary 554) between the second region 420 (gap 320) and the third region 430 (base material 200). Thus, it is possible to inhibit light advancing from the first region 410 (adhesive layer 310) side to the third region 430 (base material 200) side from being reflected on the boundary 552 and to inhibit light advancing from the third region 430 (base material 200) side to the second region 420 (gap 320) side from passing through the boundary 554. In this manner, light from the substrate 100 side may be emitted from the surface 204 of the base material 200 with high efficiency, and light from the base material 200 side can be inhibited from leaking from the surface 102 of the substrate 100.

In addition, the refractive index of the fourth region 440 (substrate 100) may be closer to the refractive index of the first region 410 (adhesive layer 310) than to the refractive index of the second region 420 (gap 320). In other words, the absolute value of a refractive index difference between the fourth medium 540 (substrate 100) and the first medium 510 (adhesive layer 310) may be smaller than the absolute value of a refractive index difference between the fourth medium 540 (substrate 100) and the second medium 520 (gap 320). In this case, the light reflectance on an interface (boundary 556) between the fourth region 440 (substrate 100) and the first region 410 (adhesive layer 310) is smaller than the light reflectance on an interface (boundary 558) between the fourth region 440 (substrate 100) and the second region 420 (gap 320). Thus, it is possible to inhibit light advancing from the fourth region 440 (substrate 100) side to the first region 410 (adhesive layer 310) side from being reflected on the boundary 556 and to inhibit light advancing from the second region 420 (gap 320) side to the fourth region 440 (substrate 100) side from passing through the boundary 558. In this manner, light from the substrate 100 side may be emitted from the surface 204 of the base material 200 with high efficiency, and light from the base material 200 side can be inhibited from leaking from the surface 102 of the substrate 100.

Further, a refractive index of the second region 420 (gap 320) is smaller than that of the third region 430 (base material 200). In this case, when an incident angle of light advancing from the third region 430 (base material 200) side to the second region 420 (gap 320) side is large to a certain degree, a total reflection occurs on the boundary 554. Thus, it is possible to inhibit light from the base material 200 side from leaking from the surface 102 of the substrate 100. In addition, at this time, the refractive index of the second region 420 (gap 320) is smaller than that of the first region 410 (adhesive layer 310).

In addition, in a case where the refractive index of the third region 430 (base material 200) and that of the fourth region 440 (substrate 100) are different from each other, the refractive index of the first region 410 (adhesive layer 310) may be equal to or greater than the smaller one of the refractive index of the third region 430 (base material 200) and that of the fourth region 440 (substrate 100) and equal to or smaller than the greater one of the refractive index of the third region 430 (base material 200) and that of the fourth region 440 (substrate 100). In other words, the order the regions by indexes thereof from the greatest to the smallest maybe the third region 430 (base material 200), the first region 410 (adhesive layer 310), and the fourth region 440 (substrate 100), or may be the fourth region 440 (substrate 100), the first region 410 (adhesive layer 310), and the third region 430 (base material 200). In addition, in a case where the refractive index of the third region 430 (base material 200) and that of the fourth region 440 (substrate 100) are the same as each other, the refractive index of the first region 410 (adhesive layer 310) may be the same as the refractive index of the third region 430 (base material 200) and that of the fourth region 440 (substrate 100). In this case, both of the refractive index difference between the first region 410 (adhesive layer 310) and the third region 430 (base material 200) and the refractive index difference between the first region 410 (adhesive layer 310) and the fourth region 440 (substrate 100) are small. Thereby, light advancing from the fourth region 440 (substrate 100) side to the third region 430 (base material 200) side may be inhibited from reflecting on the boundary 556 and the boundary 552.

In addition, a region between the substrate 100 and the base material 200 includes the gap 320 in a region overlapping the light-transmitting region 106b. In other words, in the region overlapping the light-transmitting region 106b, no object (for example, an object in solid phase or liquid phase) which occupies a space exists in the region between the substrate 100 and the base material 200. Therefore, even when light passes through the gap 320, since there is no object functioning as a color filter which cuts a specific wavelength, the chromaticity of the light is inhibited from being changed. Thus, the chromaticity of an object visible through the substrate 100 and the base material 200 is inhibited from being significantly changed.

Next, using FIG. 1 to FIG. 5, details of the light-emitting system 20 will be described. The light-emitting system 20 includes a light-emitting device 10, a base material 200, a frame body 210, and an adhesive layer 310. The light-emitting device 10 has a substrate 100, a first electrode 110, a first terminal 112, a first wiring 114, an organic layer 120, a second electrode 130, a second terminal 132, a second wiring 134, and an insulating layer 140.

As shown in FIG. 1, the base material 200 is supported by the frame body 210. The base material 200 has light-transmitting properties, and is, for example, a glass plate. The light-emitting device 10 (substrate 100) is supported on the surface 202 of the base material 200.

As shown in FIG. 2, when viewed from a direction perpendicular to the surface 102, the shape of the substrate 100 is a rectangle having a pair of long sides and a pair of short sides. The substrate 100 includes a semi-transparent light-emitting region 106. The semi-transparent light-emitting region 106 has a plurality of light-emitting regions 106a and a plurality of light-transmitting regions 106b. These light-emitting regions 106a and light-transmitting regions 106b are alternately aligned along the long side of the substrate 100. In the example shown in the drawing, the shape of the light-emitting region 106a is a rectangle having a pair of long sides and a pair of short sides.

In the example shown in the present drawing, the plurality of light-emitting regions 106a (that is, light-emitting units 150 (details to be described later)) are aligned at a pitch which is narrow to a certain degree. Thus, in a case where light is emitted from the plurality of light-emitting units 150, the light appears to be emitted across the whole surface of the semi-transparent light-emitting region 106 to the human eye. In other words, in a case where light is emitted from the semi-transparent light-emitting region 106, an object on the surface 102 side is not visible to the human eye from the surface 204 (FIG. 4) side.

Further, in the example shown in the present drawing, the light-emitting region 106a (that is, a region having light shielding properties) is narrow to a certain degree, and the light-transmitting region 106b is wide to a certain degree. Specifically, the width of the light-emitting region 106a is, for example, approximately 200 μm, and the width of the light-transmitting region 106b is, for example, approximately 700 μm. Thus, an object is visible through the light-emitting device 10 to the human eye. In other words, the light-emitting device 10 functions as a semi-transparent OLED. Specifically, in a case where light is not emitted from the semi-transparent light-emitting region 106, the object on the surface 102 side is visible from the surface 204 (FIG. 4) side to the human eye. In addition, in both of a case where light is emitted from the semi-transparent light-emitting region 106 and a case where light is not emitted from the semi-transparent light-emitting region 106, an object on the surface 204 (FIG. 4) side is visible from the surface 102 side to the human eye. Specifically, in the example shown in the drawing, a region between the surface 204 of the base material 200 and the surface 102 of the substrate 100 includes the plurality of first regions 410, the plurality of second regions 420, the third region 430, and the fourth region 440, and by setting the refractive index or an object in each region as described above, light emitted in the light-emitting region 106a is prevented from being emitted to the surface 102 side. Thus, when visually recognizing the surface 204 side from the surface 102 side through the light-emitting system 20, the surface 204 side can be easily visually recognized.

Meanwhile, in the example shown in the drawing, the shape of the semi-transparent light-emitting region 106 is defined as a rectangle having a pair of long sides and a pair of short sides. Specifically, the pair of long sides of the semi-transparent light-emitting region 106 overlaps a pair of short sides of each of the plurality of light-emitting regions 106a. One short side of the semi-transparent light-emitting region 106 overlaps an outside long side of a light-emitting region 106a at one end out of the plurality of light-emitting regions 106a. The other short side of the light-emitting region 106a overlaps an outside long side of a light-emitting region 106a at the other end out of the plurality of light-emitting regions 106a.

As shown in FIG. 3, the adhesive layer 310 includes a plurality of first portions 311 (first adhesive layer) and a second portion 313 (second adhesive layer). The plurality of first portions 311 are aligned in a row along the long side of the substrate 100, and connected to the second portion 313. Each of the plurality of first portions 311 extends along the short side of the substrate 100. The second portion 313 extends continuously along each side (edge) of the substrate 100 and surrounds the semi-transparent light-emitting region 106 (FIG. 2). Thereby, an edge of the substrate 100 is inhibited from peeling off from the base material 200.

Details of a cross section of the light-emitting system 20 will be described using FIG. 4. The substrate 100 has a surface 102 and a surface 104. The surface 104 is on the opposite side of the surface 102. The base material 200 has a surface 202 and a surface 204. The surface 204 is on the opposite side of the surface 202. The light-emitting device 10 is supported on the surface 202 of the base material 200, the surface 202 of the base material 200 facing the surface 104 of the substrate 100 with the adhesive layer 310 interposed therebetween.

The base material 200 functions as a support to support the substrate 100. Therefore, a thickness t2 of the base material 200 needs to be thicker to a certain degree than a thickness t1 of the substrate 100. Specifically, the thickness t2 of the base material 200 is equal to or greater than 100 μm and equal to or less than 10 mm, and the thickness t1 of the substrate 100 is, for example, equal to or greater than 1 μm and equal to or less than 2 mm.

The substrate 100 includes, for example, a polyimide (thickness: approximately 20 μm). As another example, the substrate 100 may be a resin sheet, a thin glass plate, or a glass substrate. Further, as still another example, the substrate 100 may be a resin substrate. In this case, the substrate 100 may include an inorganic barrier film (for example, SiNₓ or SiON) which covers the surface of the resin substrate. Thus, it is possible to inhibit water from permeating the substrate 100. Meanwhile, the inorganic barrier film is formed by, for example, sputtering, Atomic Layer Deposition (ALD), or Chemical Vapor Deposition (CVD). Further, the inorganic barrier film may be formed on both surfaces of the substrate 100 or only on either surface thereof.

The first electrode 110 is on the surface 102 of the substrate 100. The first electrode 110 has conductivity and light-transmitting properties. The first electrode 110 is formed of, for example, an indium tin oxide (ITO), or an indium zinc oxide (IZO). As shown in FIG. 2 and FIG. 5, each of a plurality of first electrodes 110 is connected to the first terminal 112 through respective ones of a plurality of first wirings 114. Thereby, it is possible to apply voltage to the first electrode 110 from the outside of the light-emitting device 10 through the first terminal 112 and the first wirings 114.

The insulating layer 140 is composed of, for example, an organic material, more specifically, for example, polyimide. The insulating layer 140 includes an opening 142. The opening 142 exposes a portion of the first electrode 110.

The organic layer 120 is on the first electrode 110 and the insulating layer 140. The organic layer 120 includes, for example, a hole injection layer, a hole transport layer, a light-emitting layer, an electron transport layer, and an electron injection layer. The hole injection layer and the hole transport layer are electronically connected to the first electrode 110. The electron transport layer and the electron injection layer are electronically connected to the second electrode 130. The light-emitting layer emits light by voltage between the first electrode 110 and the second electrode 130.

The second electrode 130 is on the organic layer 120. The second electrode 130 has light reflectivity and conductivity. The second electrode 130 is formed of, for example, a metal, more specifically, for example, Al, Ag, or an AgMg alloy. The second electrode 130 is formed by, for example, vacuum deposition using a metal mask. As shown in FIG. 2 and FIG. 5, each of a plurality of the second electrodes 130 is connected to the second terminal 132 through respective ones of a plurality of second wirings 134. Thereby, it is possible to apply voltage to the second electrode 130 from the outside of the light-emitting device 10 through the second terminal 132 and the second wirings 134.

The light-emitting unit 150 is defined by the opening 142 of the insulating layer 140. In other words, the insulating layer 140 defines the light-emitting unit 150. Specifically, the first electrode 110, the organic layer 120, and the second electrode 130 overlap each other inside the opening 142. Thereby, light from the organic layer 120 (more specifically, a light-emitting layer in the organic layer 120) is emitted from the opening 142.

The adhesive layer 310 has light-transmitting properties, and is formed of, for example, a resin. To form the gap 320 between the surface 104 of the substrate 100 and the surface 202 of the base material 200, a thickness t3 of the adhesive layer 310 (that is, a height t3 of the first region 410 and the second region 420) needs to be large to a certain degree, specifically, for example, equal to or greater than 10 μm and equal to or less than 10 mm.

The first electrode 110 includes an end 110a and an end 110b, the organic layer 120 includes an end 120a and an end 120b, the second electrode 130 includes an end 130a and an end 130b, the insulating layer 140 includes an end 140a and an end 140b, the opening 142 includes an end 142a and an end 142b, and the adhesive layer 310 includes an end 310a and an end 310b. The end 110b, the end 120b, the end 130b, the end 140b, the end 142b, and the end 310b are oriented in the same direction as each other, and are on the opposite side of the end 110a, the end 120a, the end 130a, the end 140a, the end 142a, and the end 310a, respectively.

The end 110a and the end 110b of the first electrode 110 are covered with the insulating layer 140. Specifically, in the width direction of the light-emitting unit 150, the end 110a is between the end 140a and the end 142a of the insulating layer 140, and the end 110b is between the end 140b and the end 142b of the insulating layer 140.

The end 120a and the end 120b of the organic layer 120 are located more outside in the width direction of the light-emitting unit 150 than the end 140a and the end 140b of the insulating layer 140, respectively. However, the end 120a and the end 120b may be located more inside than the end 140a and the end 140b, respectively, and specifically, between the end 140a and the end 142a and between the end 140b and the end 142b, respectively.

The end 130a and the end 130b of the second electrode 130 may be located more inside in the width direction of the light-emitting unit 150 than the end 140a and the end 140b of the insulating layer 140, respectively, and specifically, between the end 140a and the end 142a and between the end 140b and the end 142b, respectively.

In the width direction of the light-emitting unit 150, the end 310a and the end 310b of the adhesive layer 310 are located between the end 142a and the end 130a and between the end 142b and the end 130b, respectively. Specifically, in the width direction of the light-emitting unit 150, the end 310a and the end 310b are located outside the end 142a and the end 142b, respectively, just by a distance w. In the width direction of the light-emitting unit 150, the end 130a and the end 130b are located outside the end 142a and the end 142b, respectively, just by a distance l. The distance w and the distance l satisfy 0≤w≤l. In a case where the distance w is equal to or greater than 0 (0≤w), light from the light-emitting unit 150 can be inhibited from reaching the boundary 558. In a case where the distance w is equal to or less than l (w≤l), light advancing from the adhesive layer 310 side to the substrate 100 side can be inhibited from leaking from the surface 102. Further, in a case where the distance w is equal to or less than l (w≤l), the adhesive layer 310 is not overlapped with the light-transmitting regions 106b. Thus, it is possible to inhibit the chromaticity from being changed by the adhesive layer 310. At this time, the distances w need not be the same as each other throughout one light-emitting system. In addition, the distances l need not be the same as each other throughout one light-emitting system.

Each of the plurality of light-emitting regions 106a overlaps respective ones of the plurality of light-emitting units 150, and specifically, exists from the end 142a to the end 142b in the width direction of the light-emitting unit 150. Each of the plurality of light-transmitting regions 106b exists between the second electrode 130 in one light-emitting unit 150 and the second electrode 130 in another light-emitting unit 150 adjacent to the one light-emitting unit 150, and specifically, exists from the end 130a of the second electrode 130 of the one light-emitting unit 150 to the end 130b of second electrode 130 of the other light-emitting unit 150 adjacent to the one light-emitting unit 150.

The surface 102 of the substrate 100 includes a plurality of first regions 102a, a plurality of second regions 102b, and a plurality of third regions 102c. A first region 102a exists, in the width direction of the light-emitting unit 150, from the end 130a to the end 130b of the second electrode 130. The second region 102b exists, in the width direction of the light-emitting unit 150, from the end 130a of the second electrode 130 to the end 140a of the insulating layer 140 (or from the end 130b of the second electrode 130 to the end 140b of the insulating layer 140). The third region 102c exists from the end 140a of the insulating layer 140 in one light-emitting unit 150 to the end 140b in the other light-emitting unit 150 adjacent to the one light-emitting unit 150.

In the example shown in the drawing, a width d2 of the second region 102b is narrower than a width d3 of the third region 102c. Thus, the light transmittance of the light-emitting device 10 is high. In detail, the light transmittance of the second region 102b is lower than that of the third region 102c. This is because while the insulating layer 140 is located in the second region 102b, no insulating layer 140 is located in the third region 102c. As described above, the width d2 of the second region 102b is narrower than the width d3 of the third region 102c. Thus, the light transmittance of the light-emitting device 10 is high. Further, from the viewpoint of chromaticity, when the insulating layer 140 is disposed, there is a case where the insulating layer 140 has a function as a color filter. In this case, by making the width of the second region 102b to be narrower than that of the third region 102c, the chromaticity of light transmitted through the light-emitting device 10 can be inhibited from changing, or the light-emitting device 10 itself appearing to have a hue is made less noticeable.

In addition, in the example shown in the diagram, the light-emitting device 10 is inhibited from functioning as a filter that shields light of a specific wavelength. In detail, light transmittance of the insulating layer 140 may be different depending on the wavelength. Thus, the insulating layer 140 may function as a filter to shield light of a specific wavelength. In the example shown in the diagram, as described above, the width d2 of the second region 102b (a region overlapping the insulating layer 140) is narrow, specifically, is narrower than the width d3 of the third region 102c. Thus, the light-emitting device 10 is inhibited from functioning as a filter that shields light of a specific wavelength. Further, in a case where the insulating layer 140 functions as a filter, the insulating layer 140 may be visually recognized due to a slight hue. The width d2 of the second region 102b (the region overlapping the insulating layer 140) is narrow, and specifically, the width d2 is made narrower than the width d3 of the third region 102c, thereby inhibiting the insulating layer 140 and the light-emitting device 10 themselves from having a hue.

In the example shown in the diagram, the width d2 of the second region 102b is, for example, equal to or greater than 0 times and equal to or less than 0.2 times (0≤d2/d1≤0.2) a width d1 of the first region 102a. The width d3 of the third region 102c is, for example, equal to or greater than 0.3 times and equal to or less than 2 times (0.3≤d3/d1≤2) a width d1 of the first region 102a. The width d1 of the first region 102a is, for example, equal to or greater than 50 μm and equal to or less than 500 μm. The width d2 of the second region 102b is, for example, equal to or greater than 0 μm and equal to or less than 100 μm. The width d3 of the third region 102c is equal to or greater than 15 μm and equal to or less than 1,000 μm.

Meanwhile, the plurality of light-emitting units 150 are sealed from an outside region. In one example, the plurality of light-emitting units 150 are sealed by a sealing plate having a barrier film. In this case, the sealing plate is adhered with an adhesive. Further in this case, a desiccant may be filled between the sealing plate and the plurality of light-emitting units 150. As another example, the plurality of light-emitting units 150 may be sealed by an inorganic film (for example, an Al₂O₃ film, a Si₃N₄ film, a TiO₂ film, or a SiON film) formed by, for example, ALD, CVD, or sputtering, or a laminated film of these inorganic films.

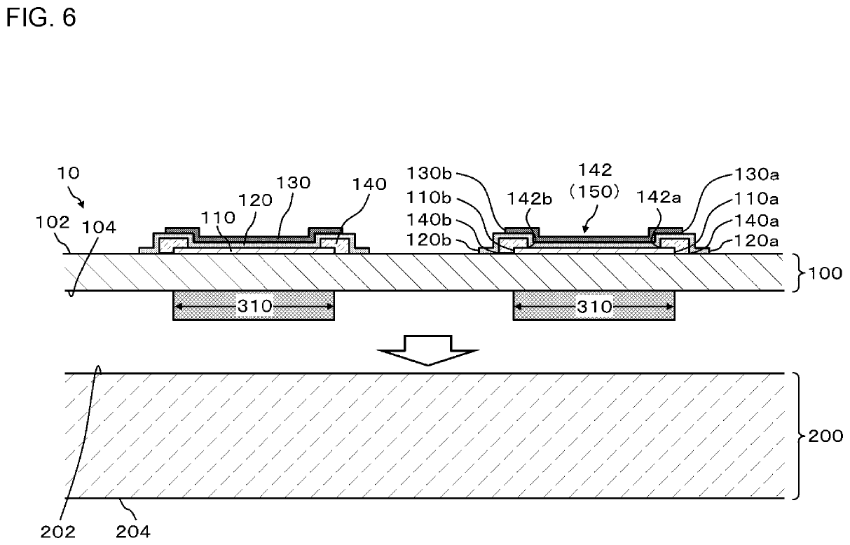

FIG. 6 is a diagram to explain a first exemplary method to join the light-emitting device 10 shown in FIG. 1-FIG. 5 to the base material 200. In the example shown in the diagram, first, the adhesive layer 310 is formed on the surface 104 of the substrate 100. Patterning of the adhesive layers 310 is formed using, for example, a dispenser. As another example, the patterning of the adhesive layer 310 may be formed by coating by screen printing, by using a photosensitive material patterned by photolithography, or by transferring the adhesive layer 310 only to necessary portions on the surface 104. Next, the surface 104 of the substrate 100 is pressed against the surface 202 of the base material 200 with the adhesive layer 310 interposed therebetween. Thereby, the light-emitting device 10 is joined to the base material 200 with the adhesive layer 310 interposed therebetween.

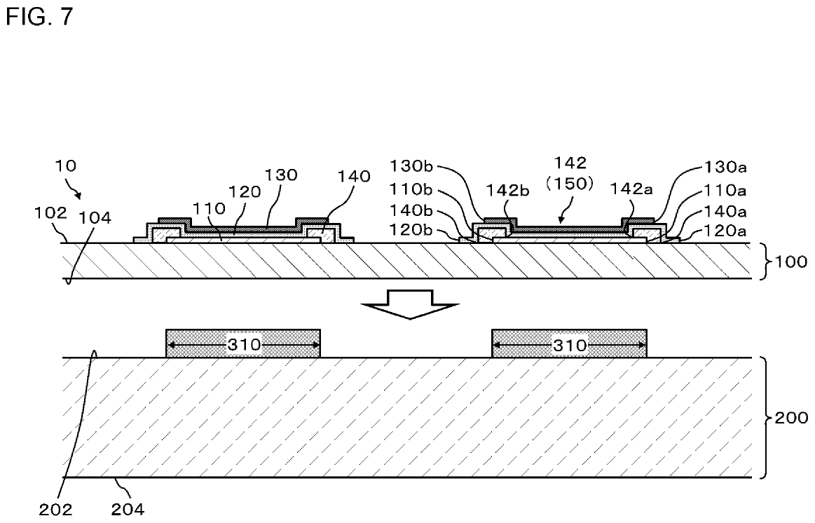

FIG. 7 is a diagram to explain a second exemplary method to join the light-emitting device 10 shown in FIG. 1-FIG. 5 to the base material 200. In the example shown in the diagram, first, the adhesive layer 310 is formed on the surface 202 of the base material 200. Next, the surface 104 of the substrate 100 is pressed against the surface 202 of the base material 200 with the adhesive layer 310 interposed therebetween. Thereby, the light-emitting device 10 is joined to the base material 200 with the adhesive layer 310 interposed therebetween.

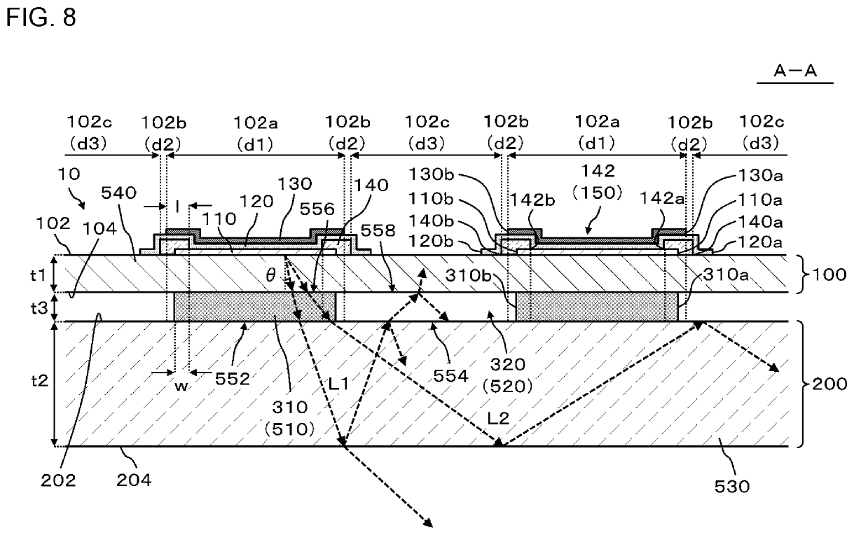

FIG. 8 is a diagram to explain the operation of the light-emitting system 20 shown in FIG. 1-FIG. 5 and corresponds to FIG. 4.

In the example shown in the diagram, the end 310a and the end 310b of the adhesive layer 310 are located, in the width direction of the light-emitting unit 150, outside the end 142a and the end 142b, respectively, just by the distance w. In this case, light emitted at an emission angle θ from an end of the light-emitting unit 150 (immediately below the end 142a or the end 142b) can be incident on the adhesive layer 310 when the emission angle θ is equal to or less than tan⁻¹(w/t1) (θ≤tan⁻¹(w/t1)) (t1: thickness of the substrate 100). At this time, the smaller t1 is, the more light can be incident on the adhesive layer 310. In other words, the smaller the thickness of the substrate 100 is, the more light can be incident on the adhesive layer 310.

In the example shown in the diagram, a light L1 is emitted from the light-emitting unit 150, and transmitted through the substrate 100, the adhesive layers 310, and the base material 200. The surface 204 of the base material 200 is in contact with air. Thus, some components of the light L1 are emitted from the surface 204 of the base material 200, and the other components of the light L1 are reflected on the surface 204 of the base material 200 by a refractive index difference between the base material 200 and air. A portion of the components reflected on the surface 204 is reflected on the boundary 554, and the other portion of the components reflected on the surface 204 passes through the boundary 554. The portion of the components which passed through the boundary 554 is reflected on the boundary 558, and the other portion of the components which passed through the boundary 554 passes through the boundary 558.

In the example shown in the diagram, a light L2 is emitted from the light-emitting unit 150 at a larger emission angle than an emission angle of the light L1, and passes through the substrate 100, the adhesive layer 310, and the base material 200, and is reflected on the surface 204 of the base material 200 and then reflected on the boundary 554. As for the light L2, a total reflection occurs on the surface 204 of the base material 200 and on the boundary 554.

As described above, the absolute value of a refractive index difference between the adhesive layer 310 and the base material 200 is smaller than the absolute value of a refractive index difference between the gap 320 and the base material 200. In this case, it is possible to inhibit light advancing from the adhesive layer 310 side to the base material 200 side (for example, light L1 and light L2 shown in the present diagram) from being reflected on the boundary 552 and to inhibit light advancing from the base material 200 side to the gap 320 side (for example, light L1 and light L2 shown in the present diagram) from passing through the boundary 554.

Further, as described above, the absolute value of the refractive index difference between the substrate 100 and the adhesive layer 310 may be smaller than the absolute value of the refractive index difference between the substrate 100 and the gap 320. In this case, it is possible to inhibit light advancing from the substrate 100 side to the adhesive layer 310 side (for example, light L1 and light L2 shown in the present diagram) from being reflected on the boundary 556 and to inhibit light advancing from the gap 320 side to the substrate 100 side (for example, light L1 shown in the present diagram) from passing through the boundary 558.

Further, as described above, the refractive index of the gap 320 is smaller than that of the base material 200. In this case, when an incident angle of light advancing from the base material 200 side to the gap 320 side (for example, light L2 shown in the present diagram) is large to a certain degree, a total reflection occurs on the boundary 554. In this manner, it is possible to inhibit light from the base material 200 side from leaking from the surface 102 of the substrate 100. Further, at this time, the refractive index of the gap 320 is smaller than that of the adhesive layer 310.

Further, light reflected on the surface 204 of the base material 200 and advancing from the base material 200 side to the adhesive layer 310 side passes through the boundary 552 and the boundary 556 and reaches the light-emitting unit 150. In this case, since the light-emitting unit 150 has light shielding properties, it is possible to inhibit light from the base material 200 side from leaking from the surface 102 of the substrate 100.

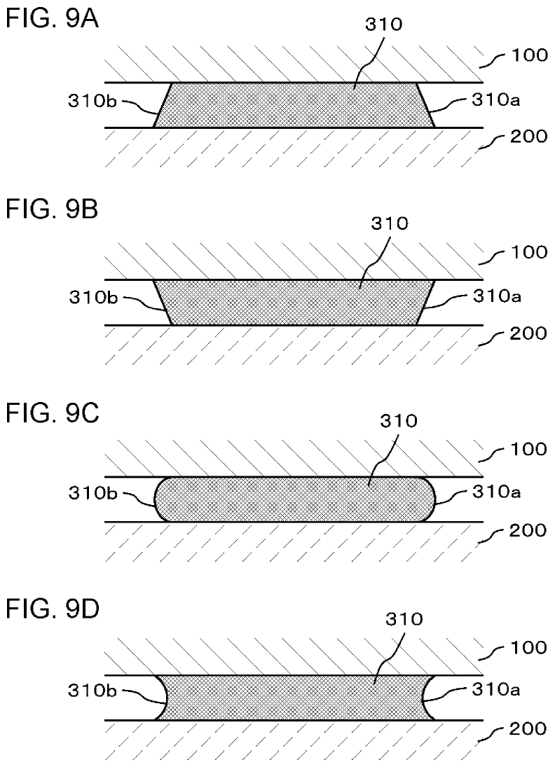

FIG. 9(a) is a diagram to explain a first example of the adhesive layer 310 shown in FIG. 1-FIG. 5. The shape of the adhesive layer 310 changes depending on the wettability of the substrate 100 and the base material 200 with respect to the adhesive layer 310. In the example shown in the diagram, the end 310a and the end 310b of the adhesive layer 310 are inclined so that the width of the adhesive layer 310 becomes narrower from the base material 200 side toward the substrate 100 side.

FIG. 9(b) is a diagram to explain a second example of the adhesive layer 310 shown in FIG. 1-FIG. 5. In the example shown in the diagram, the end 310a and the end 310b of the adhesive layer 310 are inclined so that the width of the adhesive layer 310 becomes wider from the base material 200 side toward the substrate 100 side.

FIG. 9(c) is a diagram to explain a third example of the adhesive layer 310 shown in FIG. 1-FIG. 5. In the example shown in the diagram, the end 310a and the end 310b of the adhesive layer 310 are convexly curved outward.

FIG. 9(d) is a diagram to explain a fourth example of the adhesive layer 310 shown in FIG. 1-FIG. 5. In the example shown in the diagram, the end 310a and the end 310b of the adhesive layer 310 are concavely curved outward.

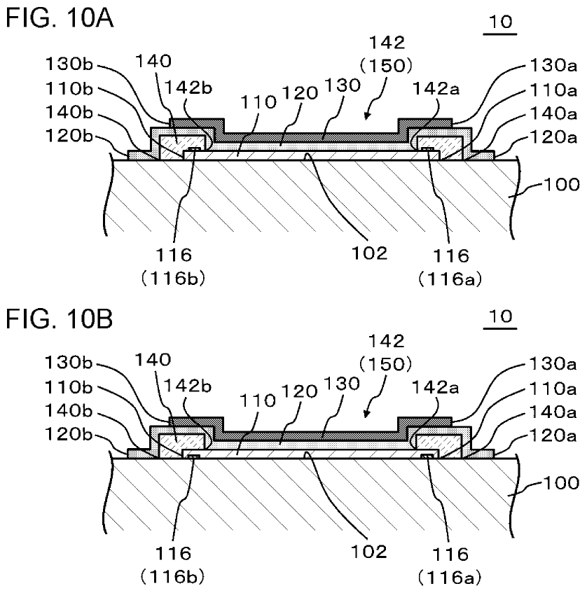

FIG. 10(a) is a diagram to explain a first example of details of the light-emitting unit 150 shown in FIG. 4. In the example shown in the diagram, the light-emitting device 10 includes two conductive portions 116 (conductive portion 116a and conductive portion 116b). The conductive portion 116a and the conductive portion 116b exist on the upper surface of the first electrode 110. The conductive portion 116a and the conductive portion 116b are covered with the insulating layer 140, and in the width direction of the light-emitting unit 150, the conductive portion 116a and the conductive portion 116b exist between the end 140a and the end 142a, and between the end 140b and the end 142b, respectively. Meanwhile, the light-emitting unit 150 may have only one of the two conductive portions 116 (conductive portion 116a and conductive portion 116b).

The conductive portion 116 functions as an auxiliary electrode of the first electrode 110. Specifically, the conductivity of the conductive portion 116 is higher than that of the first electrode 110. The conductive portion 116 is formed of a Mo/Al/Mo laminate, or an APC (Ag—Pd—Cu) alloy. Meanwhile, the conductive portion 116 is not overlapped with the light-emitting unit 150. Thus, the conductive portion 116 need not have light-transmitting properties and may have light shielding properties.

FIG. 10(b) is a diagram to explain a second example of the detail of the light-emitting unit 150 shown in FIG. 4. As shown in the diagram, the conductive portion 116a and the conductive portion 116b may be covered with the first electrode 110 on the surface 102 of the substrate 100. The conductive portion 116a and the conductive portion 116b exist, in the width direction of the light-emitting unit 150, between the end 140a and the end 142a, and between the end 140b and the end 142b, respectively. Meanwhile, the light-emitting unit 150 may include only one of the conductive portions 116a and 116b.

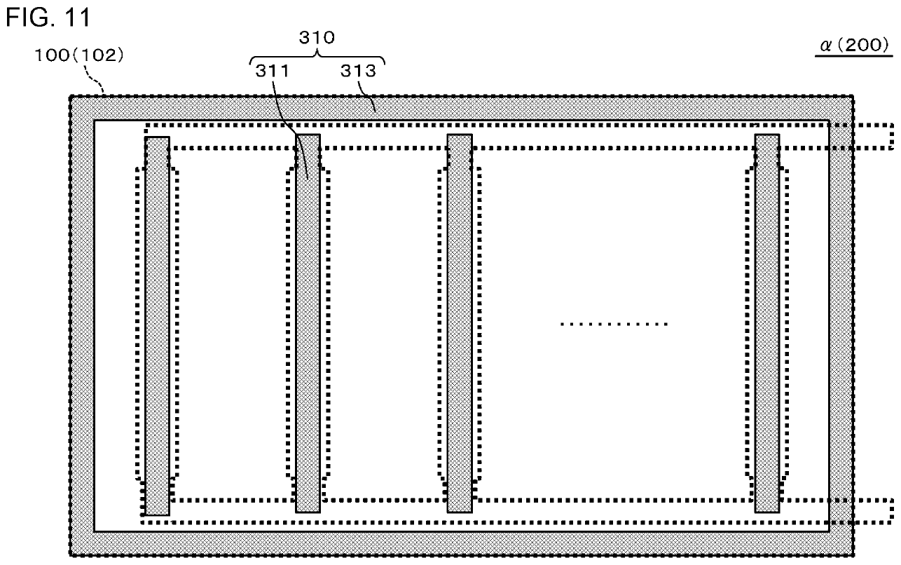

FIG. 11 is a diagram showing a first modification example of FIG. 3. As shown in the present diagram, the first portions 311 of the adhesive layer 310 need not be connected to the second portion 313 of the adhesive layer 310. Thereby, heat is inhibited from being accumulated between the first portions 311 adjacent to each other.

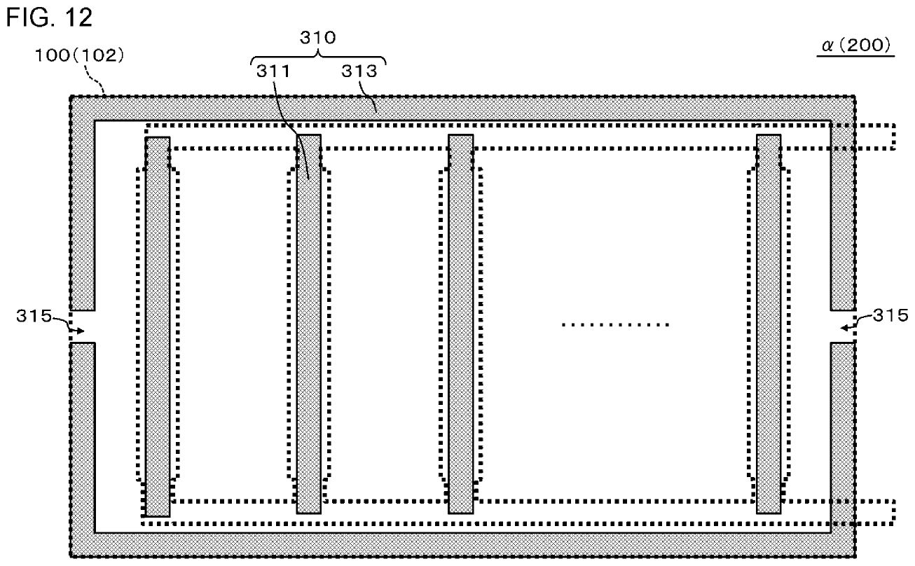

FIG. 12 is a diagram showing a second modification example of FIG. 3. As shown in the diagram, the second portion 313 of the adhesive layer 310 may include gaps 315. The second portion 313 is divided by the gaps 315. In this case, even when thermal expansion occurs in the second portions 313, it is possible to relieve stress applied to the substrate 100 by the gaps 315.

As stated above, according to the present embodiment, the light-emitting system 20 includes the gap 320 between the surface 102 of the substrate 100 and the surface 204 of the base material 200, more specifically, between the surface 104 of the substrate 100 and the surface 202 of the base material 200. Light advancing from the base material 200 side to the substrate 100 side is reflected to the base material 200 side by the gap 320. Thus, it is possible to inhibit light from the base material 200 side from leaking from the surface 102 of the substrate 100. Further, no object which occupies a space exists in the gap 320. Therefore, the chromaticity of the object which is visible through the substrate 100 and the base material 200 is inhibited from being significantly changed.

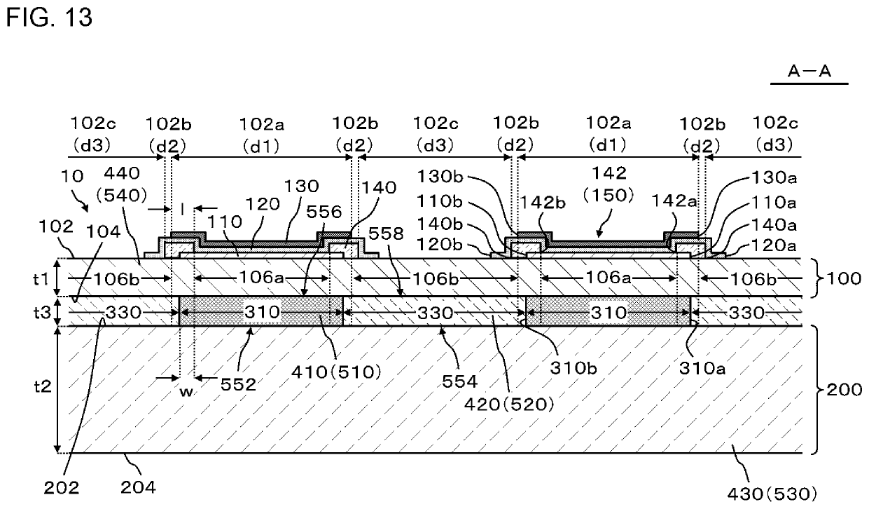

FIG. 13 is a diagram showing a first modification example of FIG. 4. The example shown in the diagram is the same as the example shown in FIG. 4, except that the light-emitting system 20 includes a member 330 instead of the gap 320 (FIG. 4). In other words, in the example shown in the diagram, the member 330 functions as the second region 420 and the second medium 520. The member 330 functions as, for example, a light-transmitting spacer member, and formed of, for example, glass or a resin. In this case, the height t3 of a region between the surface 104 of the substrate 100 and the surface 202 of the base material 200 is stably determined depending on the height of the member 330. Further, the adhesive layer 310 is prevented from spreading in the lateral direction by the member 330.

The refractive index of the member 330 may be smaller than that of the base material 200. In this case, when the incident angle of light advancing from the base material 200 side to the member 330 side is large to a certain degree, total reflection occurs on the boundary 554. Thus, it is possible to inhibit light from the base material 200 side from leaking from the surface 102 of the substrate 100.

In addition, the refractive index of the member 330 is preferably smaller than that of the substrate 100 and that of the base material 200, and the refractive index of the adhesive layer 310 is preferably closer to that of the substrate 100 and that of the base material 200 than to that of the member 330. In other words, the refractive index of the member 330 is preferably smaller than that of the adhesive layer 310. In this case, it is possible to inhibit light advancing from the substrate 100 side to the base material 200 side from being reflected on an interface between the adhesive layer 310 and the base material 200 (boundary 552) and an interface between the adhesive layer 310 and the substrate 100 (boundary 556), and it is possible to inhibit light advancing from the base material 200 side to the substrate 100 side from passing through an interface between the member 310 and the base material 200 (boundary 554) and an interface between the member 330 and the substrate 100 (boundary 558). In this manner, light from the substrate 100 side may be emitted from the surface 204 of the base material 200 with high efficiency, and light from the base material 200 side can be inhibited from leaking from the surface 102 of the substrate 100.

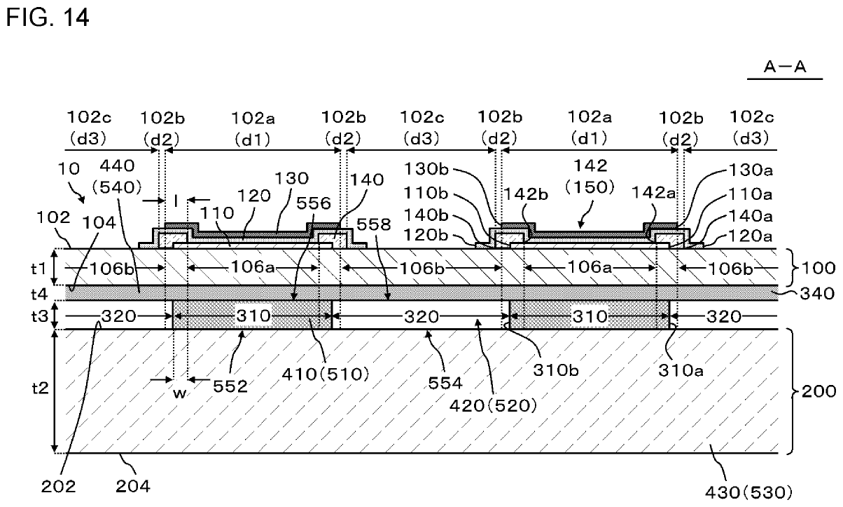

FIG. 14 is a diagram showing a second modification example of FIG. 4. The example shown in the diagram is the same as the example shown in FIG. 4, except that a function layer 340 functions as the fourth region 440. The function layer is, for example, an antireflection layer. The function layer 340 exists on the surface 104 of the substrate 100. Thus, light from the light-emitting unit 150 is inhibited from reflecting on the surface 104.

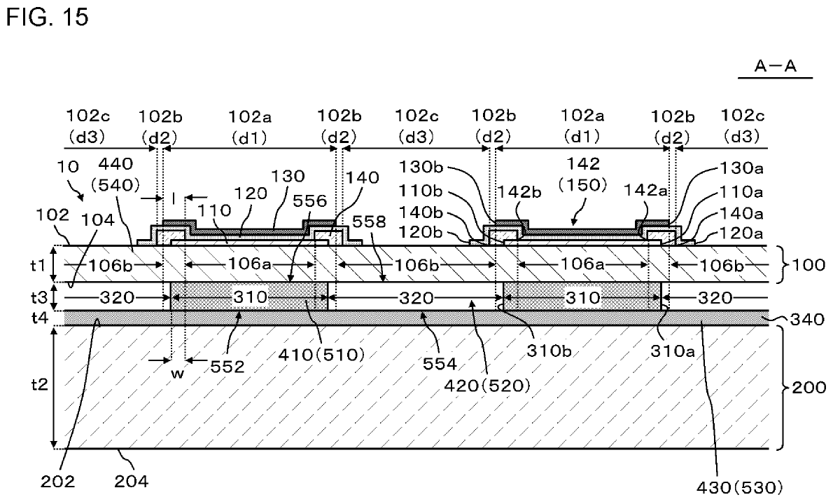

FIG. 15 is a diagram showing a third modification example of FIG. 4. The example shown in the diagram is the same as the example shown in FIG. 4, except that the function layer 340 functions as the third region 430. The function layer 340 exists on the surface 202 of the base material 200. Thus, light from the adhesive layer 310 is inhibited from reflecting on the surface 202.

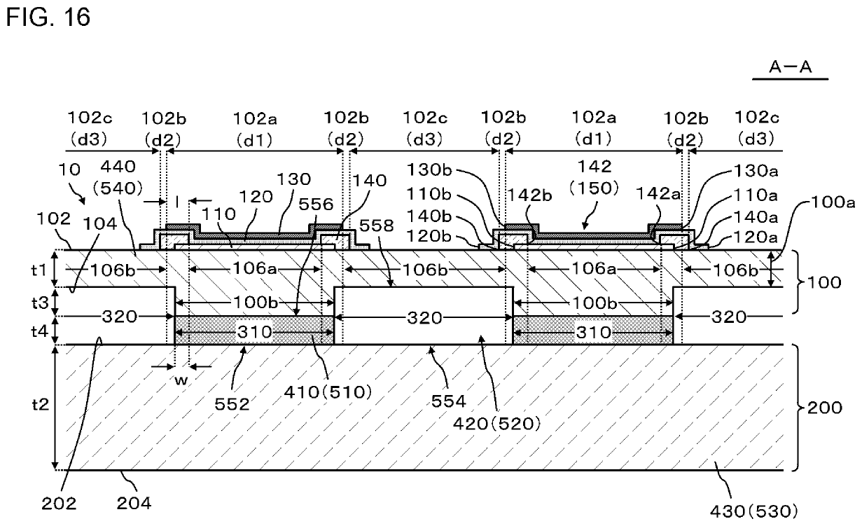

FIG. 16 is a diagram showing a fourth modification example of FIG. 4. In the example shown in the diagram, the substrate 100 includes abase 100a and a plurality of convex portions 100b. The plurality of convex portions 100b are on the surface 104 side of the substrate 100 and protrude from the base 100a. Each of the plurality of convex portions 100b overlaps respective ones of the plurality of light-emitting regions 106a. Each of the plurality of adhesive layers 310 overlaps respective ones of the plurality of convex portions 100b. In the example shown in the diagram, the boundary 552 is located between the first medium 510 (adhesive layer 310) and the third medium 530 (base material 200), the boundary 554 is located between the second medium 520 (gap 320) and the third medium 530 (base material 200), the boundary 556 is located between the first medium 510 (adhesive layer 310) and the fourth medium 540 (convex portions 100b), and the boundary 558 is located between the second medium 520 (gap 320) and the fourth medium 540 (base 100a).

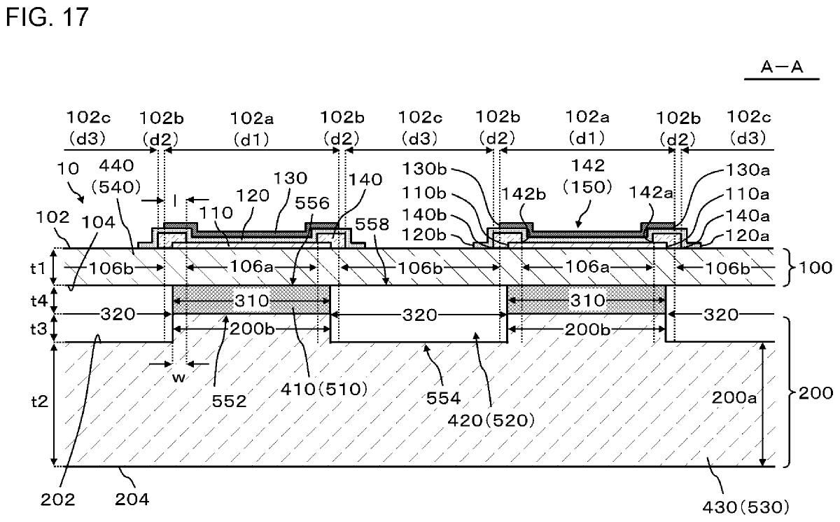

FIG. 17 is a diagram showing a fifth modification example of FIG. 4. In the example shown in the diagram, the base material 200 includes a base 200a and a plurality of convex portions 200b. The plurality of convex portions 200b are on the surface 202 side of the base material 200 and protrude from the base 200a. Each of the plurality of convex portions 200b overlaps respective ones of the plurality of light-emitting regions 106a. Each of the plurality of adhesive layers 310 overlaps respective ones of the plurality of convex portions 200b. In the example shown in the diagram, the boundary 552 is located between the first medium 510 (adhesive layer 310) and the third medium 530 (convex portion 200b), the boundary 554 is located between the second medium 520 (gap 320) and the third medium 530 (base 200a), the boundary 556 is located between the first medium 510 (adhesive layer 310) and the fourth medium 540 (substrate 100), and the boundary 558 is located between the second medium 520 (gap 320) and the fourth medium 540 (substrate 100).

### Second Embodiment

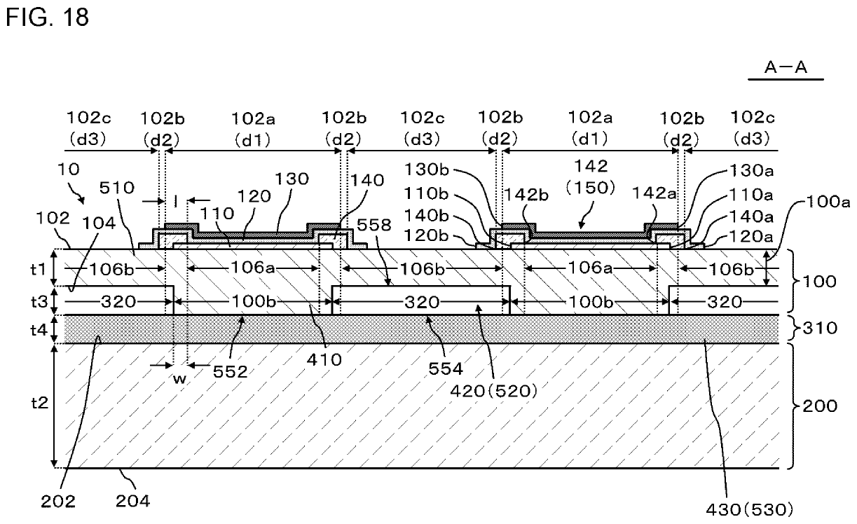

FIG. 18 is a cross-sectional view showing a light-emitting system 20 according to the second embodiment and corresponds to FIG. 4 of the first embodiment. The light-emitting system 20 according to the embodiment is the same as the light-emitting system 20 according to the first embodiment except the following points.

The light-emitting system 20 includes the adhesive layer 310 between the substrate 100 and the base material 200. The substrate 100 is supported on the surface 202 of the base material 200 so that the surface 202 of the base material 200 faces the surface 104 of the substrate 100 with the adhesive layer 310 interposed therebetween.

The substrate 100 includes the base 100a and the plurality of convex portions 100b. The plurality of convex portions 100b are on the surface 104 side of the substrate 100 and protrude from the base 100a. Each of the plurality of convex portions 100b overlaps respective ones of the plurality of light-emitting regions 106a. A region surrounded by two convex portions 100b adjacent to each other and the adhesive layer 310 functions as the gap 320. In other words, the plurality of convex portions 100b and the plurality of gaps 320 are alternately aligned.

A region between the surface 204 of the base material 200 and the surface 102 of the substrate 100 includes the plurality of first regions 410, the plurality of second regions 420, and the third region 430. Each of the plurality of first regions 410 overlaps respective ones of the plurality of light-emitting regions 106a. Each of the plurality of second regions 420 overlaps respective ones of a plurality of light-transmitting regions 106b. The third region 430 overlaps the plurality of first regions 410 and the plurality of second regions 420. The plurality of first regions 410 and the plurality of second regions 420 exist between the third region 430 and the surface 102.

In the example shown in the diagram, each of the plurality of convex portions 100b functions as each of the plurality of first regions 410, each of the plurality of gaps 320 functions as each of the plurality of second regions 420, and the adhesive layer 310 functions as the third region 430.

The region between the surface 204 of the base material 200 and the surface 102 of the substrate 100 includes the plurality of boundaries 552, the plurality of boundaries 554, and the plurality of boundaries 558. Each of the plurality of boundaries 552 is located between the first medium 510 and the third medium 530 and overlaps respective one of the plurality of light-emitting regions 106a. Each of the plurality of boundaries 554 is located between the second medium 520 and the third medium 530 and overlaps respective ones of the plurality of light-transmitting regions 106b. Each of the plurality of boundaries 558 is located between the first medium 510 and the second medium 520 and overlaps respective ones of the plurality of light-transmitting regions 106b, and located on the opposite side of the respective ones of the plurality of boundaries 554 with the second medium 520 interposed therebetween.

In the example shown in the diagram, the substrate 100 functions as the first medium 510, each of the plurality of gaps 320 functions as respective ones of the plurality of second media 520, and the adhesive layer 310 functions as the third medium 530.

The refractive index of the third region 430 (adhesive layer 310) is closer to that of the first region 410 (convex portion 100b) than to that of the second region 420 (gap 320). In other words, the absolute value of a refractive index difference between the first medium 510 (convex portion 100b) and the third medium 530 (adhesive layer 310) is smaller than the absolute value of a refractive index difference between the second medium 520 (gap 320) and the third medium 530 (adhesive layer 310). In this case, as is the case with the example shown in FIG. 4, it is possible to inhibit light advancing from the first region 410 (convex portion 100b) side to the third region 430 (adhesive layer 310) side from being reflected on the boundary 552 and to inhibit light advancing from the third region 430 (adhesive layer 310) side to the second region 420 (gap 320) side from passing through the boundary 554.

Further, the absolute value of the refractive index difference between the first medium 510 (convex portion 100b) and the third medium 530 (adhesive layer 310) may be smaller than the absolute value of the refractive index difference between the first medium 510 (base 100a) and the second medium 520 (gap 320). In this case, as is the case with the example shown in FIG. 4, it is possible to inhibit light advancing from the first medium 510 (convex portion 100b) side to the third medium 530 (adhesive layer 310) side from being reflected on the boundary 552 and to inhibit light advancing from the second region 420 (gap 320) side to the first medium 510 (convex portion 100a) side from passing through the boundary 558. Further, the refractive index of the adhesive layers 310 is preferably between the refractive index of the substrate 100 and that of the base material 200. In this case, light from the substrate 100 side can be emitted from the surface 204 of the base material 200 with high efficiency.

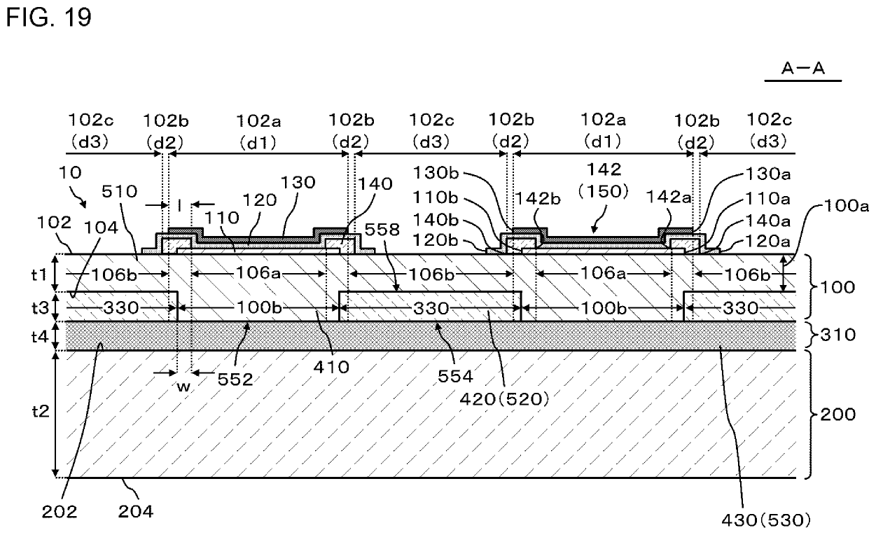

FIG. 19 is a diagram showing a first modification example of FIG. 18. The example shown in the diagram is the same as the example shown in FIG. 18, except that the light-emitting system 20 includes a member 330 instead of the gap 320 (FIG. 18). In other words, in the example shown in the diagram, the member 330 functions as the second region 420 and the second medium 520. The member 330 functions as, for example, a spacer member. In this case, the adhesive layer 310 is inhibited from entering a region between two convex portions 100b adjacent to each other. In addition, the refractive index of the member 330 is preferably smaller than that of the convex portion 100b.

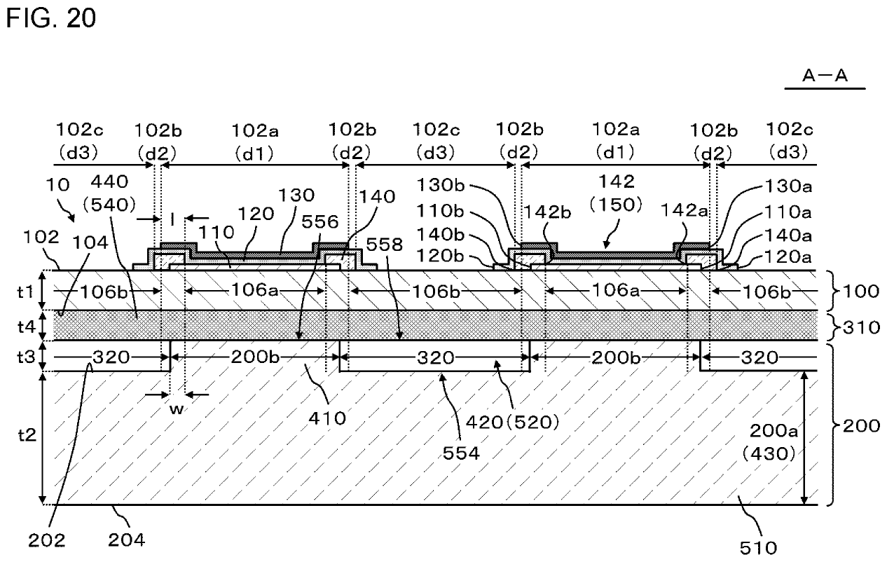

FIG. 20 is a diagram showing a second modification example of FIG. 18. The example shown in the diagram is the same as the example shown in FIG. 18 except the following points.

The base material 200 includes a base 200a and a plurality of convex portions 200b. The plurality of convex portions 200b are on a surface 202 side of the base material 200 and protrude from the base 200a. Each of the convex portions 200b overlaps respective ones of the plurality of light-emitting regions 106a. A region surrounded by two convex portions 200b adjacent to each other and the adhesive layer 310 functions as the gap 320. In other words, the plurality of convex portions 200b and the plurality of gaps 320 are alternately aligned.

The region between the surface 204 of the base material 200 and the surface 102 of the substrate 100 includes the plurality of first regions 410, the plurality of second regions 420, and the fourth region 440. Each of the plurality of first regions 410 overlaps respective ones of the plurality of light-emitting regions 106a. Each of the plurality of second regions 420 overlaps respective ones of the plurality of light-transmitting regions 106b. The fourth region 440 overlaps the plurality of first regions 410 and the plurality of second regions 420. The plurality of first regions 410 and the plurality of second regions 420 exist between the fourth region 440 and the surface 204.

In the example shown in the diagram, each of the plurality of convex portions 200b functions as each of the plurality of first regions 410, each of the plurality of gaps 320 functions as each of the plurality of second regions 420, the base 200a functions as the third region 430, and the adhesive layer 310 functions as the fourth region 440.

The region between the surface 204 of the base material 200 and the surface 102 of the substrate 100 includes the plurality of boundaries 554, the plurality of boundaries 556, and the plurality of boundaries 558. Each of the plurality of boundaries 554 is located between the first medium 510 and the second medium 520 and overlaps respective ones of the plurality of light-transmitting regions 106b. Each of the plurality of boundaries 556 is located between the first medium 510 and the fourth medium 540 and overlaps respective ones of the plurality of light-emitting regions 106a. Each of the plurality of boundaries 558 is located between the second medium 520 and the fourth medium 540 and overlaps respective ones of the plurality of light-transmitting regions 106b, and located on the opposite side of each of the plurality of boundaries 554 with the second medium 520 interposed therebetween.

In the example shown in the diagram, the base material 200 functions as the first medium 510, each of the plurality of gaps 320 functions as each of the plurality of second media 520, and the adhesive layer 310 functions as the fourth medium 540.

The refractive index of the fourth region 440 (adhesive layer 310) is closer to the refractive index of the first region 410 (convex portion 200b) than to the refractive index of the second region 420 (gap 320). In other words, the absolute value of a refractive index difference between the first medium 510 (convex portion 200b) and the fourth medium 540 (adhesive layer 310) is smaller than the absolute value of a refractive index difference between the second medium 520 (gap 320) and the fourth medium 540 (adhesive layer 310). In this case, as is the case with the example shown in FIG. 4, it is possible to inhibit light advancing from the fourth region 440 (adhesive layer 310) side to the first region 410 (convex portion 200b) side from being reflected on the boundary 556 and to inhibit light advancing from the second region 420 (gap 320) side to the fourth region 440 (adhesive layer 310) side from passing through the boundary 558.

Further, the absolute value of the refractive index difference between the first medium 510 (convex portion 200b) and the fourth medium 540 (adhesive layer 310) may be smaller than the absolute value of the refractive index difference between the first medium 510 (base 200a) and the second medium 520 (gap 320). In this case, as is the case with the example shown in FIG. 4, it is possible to inhibit light advancing from the fourth medium 540 (adhesive layer 310) side to the first medium 510 (convex portion 200b) side from being reflected on the boundary 556 and to inhibit light advancing from the third region 430 (base 200a) side to the second region 420 (gap 320) side from passing through the boundary 554. Further, the refractive index of the adhesive layer 310 is preferably between the refractive index of the substrate 100 and that of the base material 200. In this case, light from the substrate 100 side may be emitted from the surface 204 of the base material 200 with high efficiency.

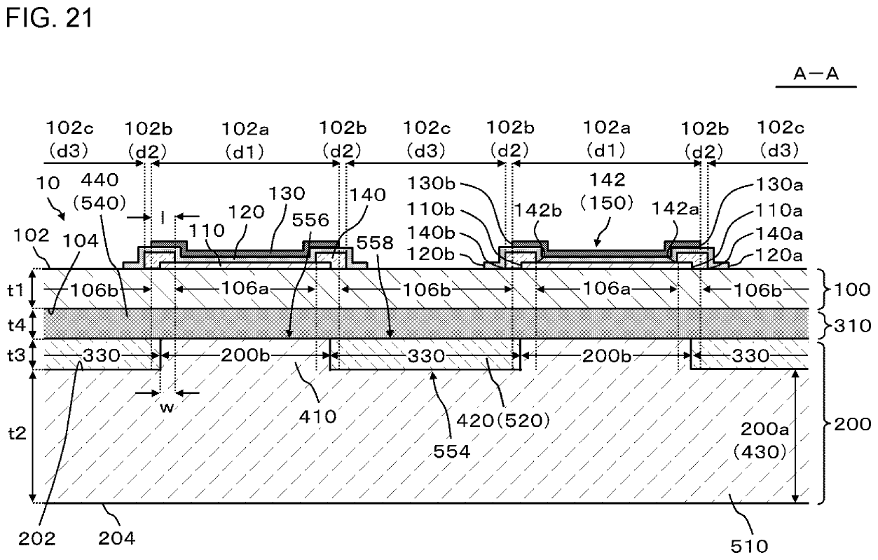

FIG. 21 is a diagram showing a third modification example of FIG. 18. The example shown in the diagram is the same as the example shown in FIG. 20, except that the light-emitting system 20 includes the member 330 instead of the gap 320 (FIG. 20). In other words, in the example shown in the diagram, the member 330 functions as the second region 420 and the second medium 520. As is the case with the example shown in FIG. 19, the member 330 functions as, for example, a spacer member. In addition, at this time, the refractive index of the member 330 is preferably smaller than that of the convex portions 200b.

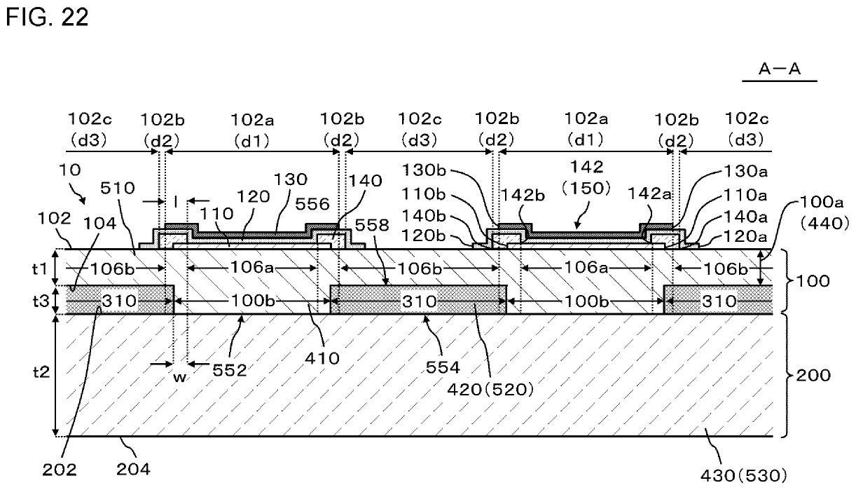

FIG. 22 is a diagram showing a fourth modification example of FIG. 18. The example shown in the diagram is the same as the example shown in FIG. 18, except that each of the plurality of convex portions 100b functions as each of the plurality of first regions 410, each of the plurality of adhesive layers 310 functions as each of the plurality of second regions 420, the base material 200 functions as the third region 430, and the base 100a functions as the fourth region 440.

The refractive index of the third region 430 (base material 200) is closer to that of the first region 410 (convex portion 100b) than to that of the second region 420 (adhesive layer 310). In other words, the absolute value of a refractive index difference between the first medium 510 (convex portion 100b) and the third medium 530 (base material 200) is smaller than the absolute value of a refractive index difference between the second medium 520 (adhesive layer 310) and the third medium 530 (base material 200). In this case, as is the case with the example shown in FIG. 4, it is possible to inhibit light advancing from the first region 410 (convex portion 100b) side to the third region 430 (base material 200) side from being reflected on the boundary 552 and to inhibit light advancing from the third region 430 (base material 200) side to the second region 420 (adhesive layer 310) from passing through the boundary 554.

Further, the absolute value of the refractive index difference between the first medium 510 (convex portion 100b) and the third medium 530 (base material 200) may be smaller than the absolute value of the refractive index difference between the first medium 510 (base 100a) and the second medium 520 (adhesive layer 310). In this case, as is the case with the example shown in FIG. 4, it is possible to inhibit light advancing from the first region 410 (convex portion 100b) side to the third region 430 (base material 200) side from being reflected on the boundary 552 and to inhibit light advancing from the second region 420 (adhesive layer 310) side to the fourth region 440 (base 100a) side from passing through the boundary 558.

In addition, the refractive index of the adhesive layer 310 is preferably smaller than that of the base material 200. In this case, when an incident angle of light advancing from the base material 200 side to the adhesive layers 310 side is large to a certain degree, a total reflection occurs on the boundary 554. Thus, it is possible to inhibit light from the base material 200 side from leaking from the surface 102 of the substrate 100.

In the example shown in the diagram, each of the plurality of adhesive layers 310 is between two convex portions 100b adjacent to each other. Therefore, the adhesive layer 310 is inhibited from spreading in the lateral direction.

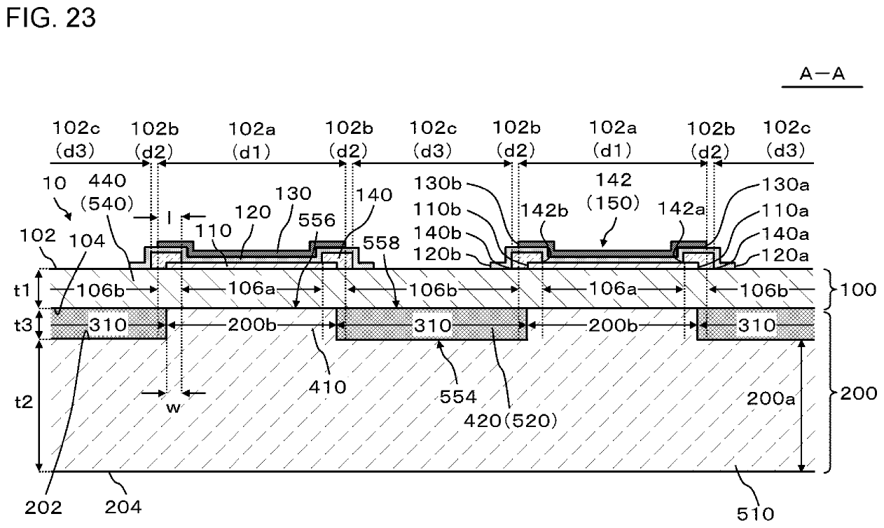

FIG. 23 is a diagram showing a fifth modification example of FIG. 18. The example shown in the diagram is the same as the example shown in FIG. 20, except that each of the plurality of convex portions 200b functions as each of the plurality of first regions 410, each of the plurality of adhesive layers 310 functions as each of the plurality of second regions 420, and the substrate 100 functions as the fourth region 440.

The refractive index of the fourth region 440 (substrate 100) is closer to the refractive index of the first region 410 (convex portion 200b) than to that of the second region 420 (adhesive layer 310). In other words, the absolute value of a refractive index difference between the first medium 510 (convex portion 200b) and the fourth medium 540 (substrate 100) is smaller than the absolute value of a refractive index difference between the second medium 520 (adhesive layer 310) and the fourth medium 540 (substrate 100). In this case, as is the case with the example shown in FIG. 4, it is possible to inhibit light advancing from the fourth region 440 (substrate 100) side to the first region 410 (convex portion 200b) side from being reflected on the boundary 556 and to inhibit light advancing from the second region 420 (adhesive layer 310) side to the fourth region 440 (substrate 100) side from passing through the boundary 558.

Further, the absolute value of the refractive index difference between the first medium 510 (convex portion 200b) and the fourth medium 540 (substrate 100) may be smaller than the absolute value of the refractive index difference between the first medium 510 (base 200a) and the second medium 520 (adhesive layer 310). In this case, as is the case with the example shown in FIG. 4, it is possible to inhibit light advancing from the fourth medium 540 (substrate 100) side to the first medium 510 (convex portion 200b) side from being reflected on the boundary 556 and to inhibit light advancing from the first medium 510 (base 200a) side to the second region 420 (adhesive layer 310) side from passing through the boundary 554.

In addition, the refractive index of the adhesive layer 310 is preferably smaller than that of the base material 200. In this case, when the incident angle of light advancing from the base material 200 side to the adhesive layers 310 side is large to a certain degree, a total reflection occurs on the boundary 554. Thus, it is possible to inhibit light from the base material 200 side from leaking from the surface 102 of the substrate 100.

In the example shown in the diagram, each of the plurality of adhesive layers 310 is between two convex portions 200b adjacent to each other. Therefore, the adhesive layer 310 is inhibited from spreading in the lateral direction.

### Third Embodiment

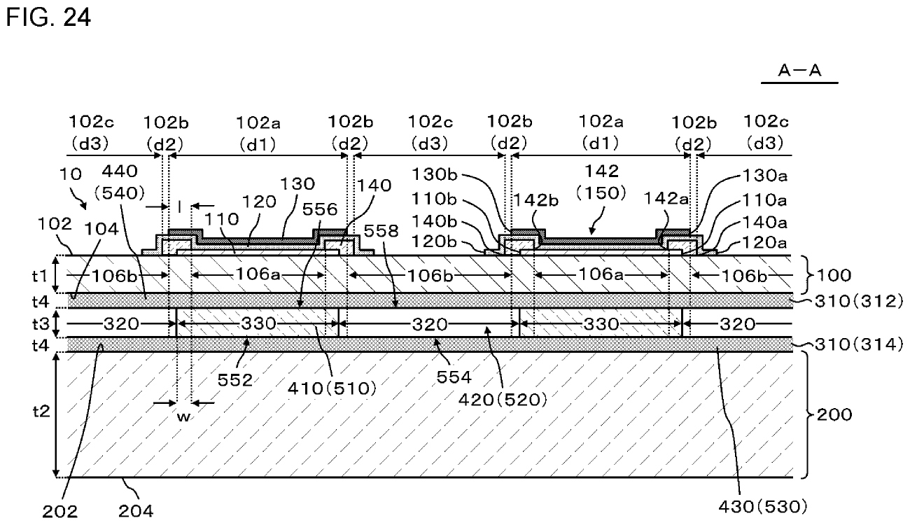

FIG. 24 is a cross sectional view of a light-emitting system 20 according to the third embodiment, and corresponds to FIG. 4 of the first embodiment. The light-emitting system 20 is the same as the light-emitting system 20 according to the first embodiment except the following points.

A region between the surface 104 of the substrate 100 and the surface 202 of the base material 200 includes two adhesive layers 310 (adhesive layer 312 and adhesive layer 314), a plurality of members 330, and a plurality of gaps 320. The adhesive layer 312 is on the surface 104 of the substrate 100. The adhesive layer 314 is on the surface 202 of the base material 200. Each of the plurality of members 330 is located between the adhesive layer 312 and the adhesive layer 314 and overlaps respective ones of a plurality of light-emitting regions 106a. Each of the plurality of gaps 320 is located between the adhesive layer 312 and the adhesive layer 314 and overlaps respective ones of the plurality of light-transmitting regions 106b.

In the example shown in the diagram, each of the plurality of members 330 functions as each of a plurality of first regions 410, each of the plurality of gaps 320 functions as each of a plurality of second regions 420, the adhesive layer 314 functions as the third region 430, and the adhesive layer 312 functions as the fourth region 440.

The refractive index of the third region 430 (adhesive layer 314) is closer to that of the first region 410 (member 330) than to that of the second region 420 (gap 320). In other words, the absolute value of a refractive index difference between the first medium 510 (member 330) and the third medium 530 (adhesive layer 314) is smaller than the absolute value of a refractive index difference between the second medium 520 (gap 320) and the third medium 530 (adhesive layer 314). In this case, as is the case with the example shown in FIG. 4, it is possible to inhibit light advancing from the first region 410 (member 330) side to the third region 430 (adhesive layer 314) side from being reflected on the boundary 552 and to inhibit light advancing from the third region 430 (adhesive layer 314) side to the second region 420 (gap 320) side from passing through the boundary 554.

In addition, the refractive index of the fourth region 440 (adhesive layer 312) may be closer to the refractive index of the first region 410 (member 330) than to the refractive index of the second region 420 (gap 320). In other words, the absolute value of a refractive index difference between the fourth medium 540 (adhesive layer 312) and the first medium 510 (member 330) is smaller than the absolute value of a refractive index difference between the fourth medium 540 (adhesive layer 312) and the second medium 520 (gap 320). In this case, as is the case with the example shown in FIG. 4, it is possible to inhibit light advancing from the fourth region 440 (adhesive layer 312) side to the first region 410 (member 330) side from being reflected on the boundary 556 and to inhibit light advancing from the second region 420 (gap 320) side to the fourth region 440 (adhesive layer 312) side from passing through the boundary 558.

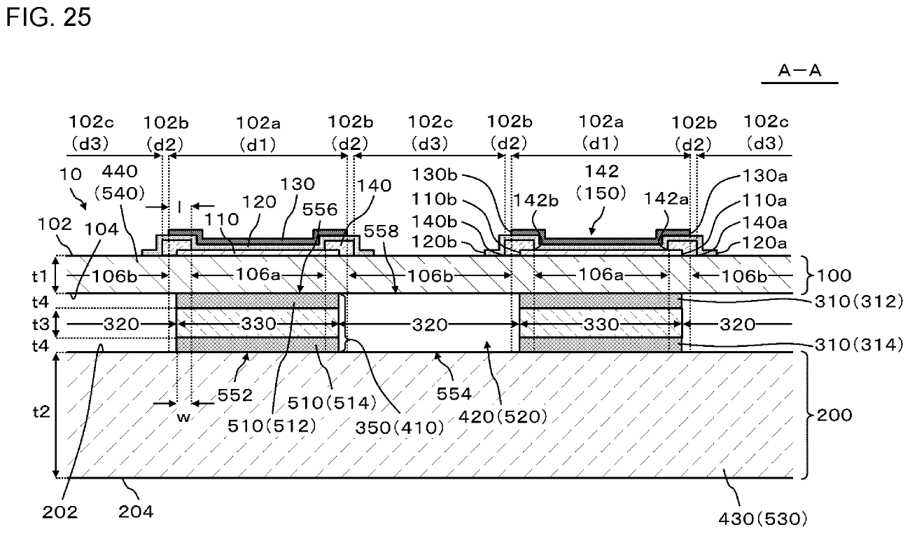

FIG. 25 is a diagram showing a modification example of FIG. 24. The example shown in the diagram is the same as the example shown in FIG. 24 except the following points.

A region between the surface 104 of the substrate 100 and the surface 202 of the base material 200 includes a plurality of laminates 350 and a plurality of gaps 320. Each of the plurality of laminates 350 overlaps respective ones of the plurality of light-emitting regions 106a. Each of the plurality of gaps 320 overlaps respective ones of the plurality of light-transmitting regions 106b. Each of the plurality of laminates 350 includes the adhesive layer 312, the member 330, and the adhesive layer 314. The adhesive layer 312 is on the surface 104 of the substrate 100. The adhesive layer 314 is on the surface 202 of the base material 200. The member 330 is between the adhesive layer 312 and the adhesive layer 314.

In the example shown in the diagram, each of the plurality of laminates 350 functions as each of the plurality of first regions 410, each of the plurality of gaps 320 functions as each of the plurality of second regions 420, the base material 200 functions as the third region 430, and the substrate 100 functions as the fourth region 440.

Further in the example shown in the diagram, the first region 410 (laminate 350) includes two first media 510 (first medium 512 and first medium 514). The first medium 512 is between the substrate 100 and the member 330. The first medium 514 is between the base material 200 and the member 330. Specifically, the adhesive layer 312 functions as the first medium 512 and the adhesive layer 314 functions as the first medium 514.

The absolute value of a refractive index difference between the first medium 514 (adhesive layer 314) and the third medium 530 (base material 200) is smaller than the absolute value of a refractive index difference between the second medium 520 (gap 320) and the third medium 530 (base material 200). In this case, as is the case with the example shown in FIG. 4, it is possible to inhibit light advancing from the first medium 514 (adhesive layer 314) side to the third medium 530 (base material 200) side from being reflected on the boundary 552 and to inhibit light advancing from the third medium 530 (base material 200) side to the second medium 520 (gap 320) from passing through the boundary 554.

In addition, the absolute value of a refractive index difference between the fourth medium 540 (substrate 100) and the first medium 512 (adhesive layer 312) may be smaller than the absolute value of a refractive index difference between the fourth medium 540 (substrate 100) and the second medium 520 (gap 320). In this case, as is the case with the example shown in FIG. 4, it is possible to inhibit light advancing from the fourth medium 540 (substrate 100) side to the first medium 512 (adhesive layer 312) side from being reflected on the boundary 556 and to inhibit light advancing from the second medium 520 (gap 320) side to the fourth medium 540 (substrate 100) from passing through the boundary 558.

### Fourth Embodiment

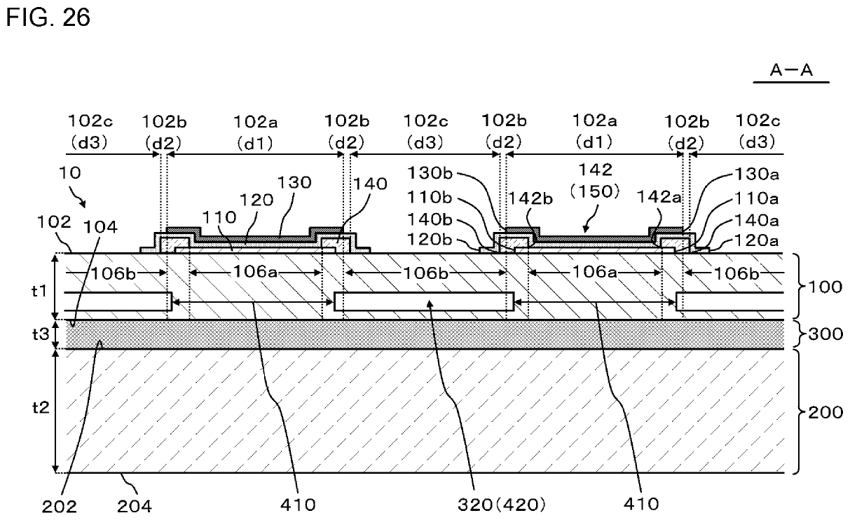

FIG. 26 is a cross sectional view of a light-emitting system 20 according to the fourth embodiment and corresponds to FIG. 4 of the first embodiment. The light-emitting system 20 is the same as the light-emitting system 20 according to the first embodiment except the following points.

In the example shown in the diagram, the light-emitting system 20 includes a plurality of gaps 320 in an inner portion of the substrate 100, specifically, between the surface 102 and the surface 104 of the substrate 100. Each of the plurality of gaps 320 overlaps respective ones of a plurality of light-transmitting regions 106b. The gap 320 functions as the second region 420, and a region between two gaps 320 adjacent to each other functions as the first region 410. There is a refractive index difference on an interface between the gap 320 and the substrate 100. Therefore, light advancing from the base material 200 side to the substrate 100 side may be reflected by the gap 320. Thus, it is possible to inhibit light from the base material 200 side from leaking from the surface 102 of the substrate 100.

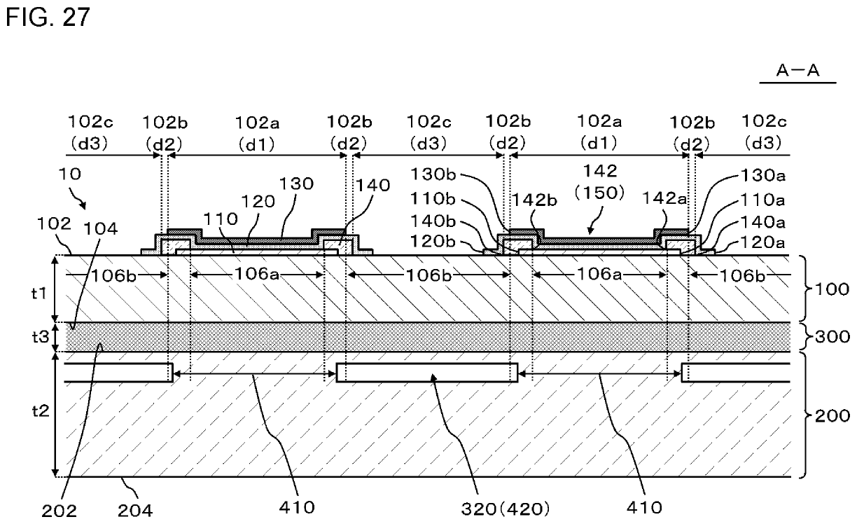

FIG. 27 is a diagram showing a modification example of FIG. 26. The example shown in the diagram is the same as the example shown in FIG. 26, except that the light-emitting system 20 includes the plurality of gaps 320 inside the base material 200, specifically, between the surface 202 and the surface 204 of the base material 200. Each of the plurality of gaps 320 overlaps respective ones of the plurality of light-transmitting regions 106b. Meanwhile, in the example shown in the diagram, the gap 320 is located separated from the surface 204 of the base material 200 by more than t2/2 (t2: thickness of the base material 200). Thereby, light reflected on the surface 204 more easily reaches the gap 320. Light advancing from the base material 200 side to the substrate 100 side may be reflected by the gap 320. Thus, it is possible to inhibit light from the base material 200 side from leaking from the surface 102 of the substrate 100.

### EXAMPLE

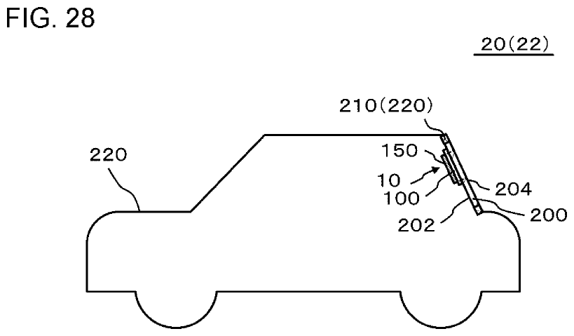

FIG. 28 is a diagram of a light-emitting system 20 according to an example. In the example shown in the diagram, the light-emitting system 20 is a mobile object 22, more specifically, an automobile. Meanwhile, the mobile object 22 is not limited to an automobile. The mobile object 22 may be, for example, a train, an airplane, or a ship. The light-emitting system 20 includes a light-emitting device 10, a base material 200, and a vehicle body 220. The light-emitting device 10 and the base material 200 shown in the present diagram are the same as the light-emitting device 10 and the base material 200 shown in FIG. 1 to FIG. 5.

In the example shown in the diagram, the base material 200 functions as a window of the mobile object 22, specifically, a rear window of an automobile. More specifically, a portion of the vehicle body 220 functions as a frame body 210. The base material 200 is installed on the frame body 210 so that a surface 202 is directed to the inside of the vehicle body 220, and that a surface 204 is directed to the outside of the vehicle body 220. Meanwhile, the base material 200 may be unremovable from the vehicle body 220 (frame body 210). In other words, the base material 200 may be a portion of the mobile object 22.

In the example shown in the diagram, the light-emitting device 10 functions as a high-mount stop-lamp or an auxiliary brake lamp. Alternatively, the light-emitting device 10 may be a turn signal lamp. Specifically, the light-emitting device 10 (substrate 100) is supported on the surface 202 of the base material 200 and is inside the vehicle body 220.

As described using FIG. 1 to FIG. 5, in the light-emitting system 20 according to the present example, light from the light-emitting device 10 is inhibited from being emitted from the surface 202 side. Therefore, light from the light-emitting device 10 is hardly emitted to the inside of the vehicle body 220 and is emitted to the outside of the vehicle body 220. Therefore, the visibility from the inside of the vehicle body 220 is not obstructed, thereby securing the visibility of a passenger, particularly the driver.

As described above, although the embodiments and the example of the present invention have been set forthwith reference to the accompanying drawings, they are merely illustrative of the present invention, and various configurations other than those stated above can be adopted.

1. A light-emitting system comprising:
a base material comprising a light-emitting first surface; and
a light-transmitting substrate comprising a second surface facing a side opposite to the base material, and a plurality of light-emitting regions and a plurality of light-transmitting regions that are alternately aligned, the light-transmitting substrate being supported by the base material,
wherein a region between the first surface and the second surface comprises:
a first region overlapping any of the plurality of light-emitting regions;
a second region overlapping any of the plurality of light-transmitting regions; and
a third region overlapping the first region and the second region, and
wherein a refractive index of the third region is closer to a refractive index of the first region than to a refractive index of the second region.

2. The light-emitting system according to claim 1,
wherein a region between the base material and the substrate comprises a plurality of the second regions, and
wherein the plurality of second regions comprise two second regions adjacent to each other with the first region interposed therebetween.

3. The light-emitting system according to claim 1, further comprising an adhesive layer between the base material and the substrate,
wherein the adhesive layer functions as the first region.

4. The light-emitting system according to claim 1,
wherein the substrate comprises a convex portion on a side opposite to the second surface, and
wherein the convex portion functions as the first region.

5. The light-emitting system according to claim 1, further comprising a member between the base material and the substrate,
wherein the member functions as the first region.

6. The light-emitting system according to claim 1, further comprising:
a light-transmitting first electrode on the second surface of the substrate, the first electrode overlapping the first region; and
a light-reflective second electrode on the second surface of the substrate, the second electrode overlapping the first region,
wherein the second electrode comprises a first end,
wherein the first region comprises a first end facing a same direction as the first end of the second electrode, and
wherein the first end of the first region is located more inside than the first end of the second electrode.

7. The light-emitting system according to claim 1,
wherein the region between the first surface and the second surface comprises a fourth region facing the third region with the first region and the second region interposed therebetween, and
wherein a refractive index of the first region is:
equal to or greater than a smaller one of a refractive index of the third region and a refractive index of the fourth region and equal to or less than a greater one of the refractive index of the third region and the refractive index of the fourth region; or
equal to both the refractive index of the third region and the refractive index of the fourth region.

8. The light-emitting system according to claim 7,
wherein the substrate functions as the fourth region.

9. The light-emitting system according to claim 7, further comprising a function layer on a side opposite to the second surface of the substrate,
wherein the function layer functions as the fourth region.

10. The light-emitting system according to claim 1,
wherein the base material is a window of a mobile object.

11. The light-emitting system according to claim 1,
wherein the base material is a portion of a mobile object.

12. A light-emitting system comprising:
a base material comprising a light-emitting first surface; and
a light-transmitting substrate comprising a second surface facing a side opposite to the base material, and a plurality of light-emitting regions and a plurality of light-transmitting regions that are alternately aligned, the light-transmitting substrate being supported by the base material,
wherein a region between the first surface and the second surface comprises:
a first boundary between a first medium and a third medium, the first boundary overlapping any of the plurality of light-emitting regions; and
a second boundary between a second medium and the third medium, the second boundary overlapping any of the plurality of light-transmitting regions, and
wherein an absolute value of a refractive index difference between the first medium and the third medium is smaller than an absolute value of a refractive index difference between the second medium and the third medium.

13. The light-emitting system according to claim 12, further comprising a fourth medium facing the third medium with the first medium and the second medium interposed therebetween,
wherein a region between the base material and the substrate comprises:
a third boundary between the first medium and the fourth medium, the third boundary overlapping any of the plurality of light-emitting regions; and
a fourth boundary between the second medium and the fourth medium, the fourth boundary overlapping any of the plurality of light-transmitting regions, and
wherein an absolute value of a refractive index difference between the first medium and the fourth medium is smaller than an absolute value of a refractive index difference between the second medium and the fourth medium.

14. The light-emitting system according to claim 13,
wherein the region between the first surface and the second surface comprises an adhesive layer and a gap,
wherein the adhesive layer functions as the first medium,
wherein the gap functions as the second medium,
wherein the base material functions as the third medium, and
wherein the substrate functions as the fourth medium.

15. The light-emitting system according to claim 12,
wherein the region between the first surface and the second surface comprises a third boundary on a side opposite to the second boundary with the second medium therebetween, the third boundary located between the first medium and the second medium, and
wherein an absolute value of a refractive index difference between the first medium and the third medium is smaller than an absolute value of a refractive index difference between the first medium and the second medium.

16. The light-emitting system according to claim 15,
wherein the region between the first surface and the second surface comprises an adhesive layer and a gap,
wherein the substrate functions as the first medium,
wherein the gap functions as the second medium, and
wherein the adhesive layer functions as the third medium.

17. A light-emitting system comprising:
a base material comprising a light-emitting first surface; and
a light-transmitting substrate comprising a second surface facing a side opposite to the base material, and a plurality of light-emitting regions and a plurality of light-transmitting regions that are alternately aligned, the light-transmitting substrate supported by the base material,
wherein a region between the first surface and the second surface comprises:
a first region overlapping any of the plurality of light-emitting regions; and
a second region overlapping any of the plurality of light-transmitting regions, and
wherein a refractive index of the second region is smaller than a refractive index of the first region.
